(19) United States
(12) Patent Application Publication
(10) Pub. No.: US 2026/0129943 A1
(43) Pub. Date: May 7, 2026

(54) SEMICONDUCTOR DEVICE WITH ANTI-OXIDATION LAYER

(71) Applicant: SAMSUNG ELECTRONICS CO., LTD., Suwon-si (KR)

(72) Inventors: Jingyu PARK, Suwon-si (KR); Dae Wee KONG, Suwon-si (KR); Youngsu NOH, Suwon-si (KR); Geumbi MUN, Suwon-si (KR); Mingyo BYEON, Suwon-si (KR); Myung Mo AHN, Suwon-si (KR); Byeongsun YOO, Suwon-si (KR); Yoonji LEE, Suwon-si (KR); Seongyeop JEONG, Suwon-si (KR); Yeonsu JEONG, Suwon-si (KR)

(73) Assignee: SAMSUNG ELECTRONICS CO., LTD., Suwon-si (KR)

(21) Appl. No.: 19/212,060

(22) Filed: May 19, 2025

(30) Foreign Application Priority Data
Nov. 7, 2024 (KR) 10-2024-0156742

(51) Int. Cl. H10D 64/27; H10B 12/00; H10B 61/00; H10B 63/00; H10B 63/10; H10D 30/01

(52) U.S. Cl. CPC H10D 64/514; H10D 30/023; H10B 12/482; H10B 61/22; H10B 63/10; H10B 63/30

(57) ABSTRACT

A semiconductor device includes gate electrodes spaced apart from each other on a lower structure in a horizontal direction parallel to an upper surface of the lower structure, an insulating layer between the gate electrodes, and an anti-oxidation layer between each of the gate electrodes and the insulating layer. The anti-oxidation layer includes a metal carbide.

### CROSS-REFERENCE TO RELATED APPLICATIONS

This application claims priority under 35 U.S.C. § 119 to Korean Patent Application No. 10-2024-0156742, filed on Nov. 7, 2024, the disclosure of which is incorporated by reference in its entirety.

### BACKGROUND

### 1. Field

The present disclosure relates to semiconductor devices, and more particularly, to a semiconductor device including field effect transistors and a method for manufacturing the same.

### 2. Description of Related Art

A semiconductor device includes an integrated circuit composed of metal-oxide-semiconductor field effect transistors (MOSFETs). As a size and/or a design rule of the semiconductor device are gradually decreasing, scaling down of the MOSFETs is also gradually being accelerated. As the MOSFETs are gradually scaled down, operation characteristics of the semiconductor device may be deteriorated. Accordingly, research on various methods for overcoming limitations that may be caused by high-integration of the semiconductor device and forming the semiconductor device with improved performance is being conducted.

### SUMMARY

The present disclosure provides a semiconductor device including transistors which may have improved electrical characteristics, when to related semiconductor devices, and a method for manufacturing the same.

The present disclosure also provides a semiconductor device that may be easily highly-integrated, and a method for manufacturing the same.

According to an aspect of the present disclosure, a semiconductor device includes gate electrodes spaced apart from each other on a lower structure in a horizontal direction parallel to an upper surface of the lower structure, an insulating layer between the gate electrodes, and an anti-oxidation layer between each of the gate electrodes and the insulating layer. The anti-oxidation layer includes a metal carbide.

According to an aspect of the present disclosure, a semiconductor device includes a bit line extending on a substrate in a first direction parallel to an upper surface of the substrate, a vertical semiconductor patterns spaced apart from each other on the bit line in the first direction, and extending in a vertical direction vertical to the upper surface of the substrate, a gate electrodes spaced apart from each other between the vertical semiconductor patterns in the first direction, and extending in a second direction parallel to the upper surface of the substrate and crossing the first direction, an insulating layer between the gate electrodes, and an anti-oxidation layer between each of the gate electrodes and the insulating layer. The anti-oxidation layer includes carbon.

Additional aspects may be set forth in part in the description which follows and, in part, may be apparent from the description, and/or may be learned by practice of the presented embodiments.

### BRIEF DESCRIPTION OF THE FIGURES

The above and other aspects, features, and advantages of certain embodiments of the present disclosure may be more apparent from the following description taken in conjunction with the accompanying drawings, in which:

FIG. 1 is a cross-sectional view schematically illustrating a semiconductor device, according to one or more embodiments of the present disclosure;

FIG. 2 is an enlarged diagram of part P1 of FIG. 1, according to one or more embodiments of the present disclosure;

FIGS. 3 and 4 are cross-sectional views schematically illustrating a method for manufacturing a semiconductor device, according to one or more embodiments of the present disclosure;

FIG. 5 is a cross-sectional view schematically illustrating a semiconductor device, according to one or more embodiments of the present disclosure;

FIG. 6 is an enlarged diagram of part P2 of FIG. 5, according to one or more embodiments of the present disclosure;

FIGS. 7 and 8 are cross-sectional views schematically illustrating a method for manufacturing a semiconductor device, according to one or more embodiments of the present disclosure;

FIG. 9 is a block diagram illustrating a semiconductor device, according to one or more embodiments of the present disclosure;

FIGS. 10 and 11 are perspective views briefly illustrating a semiconductor device, according to one or more embodiments of the present disclosure;

FIG. 12 is a plan view of a semiconductor device, according to one or more embodiments of the present disclosure;

FIG. 13 is a cross-sectional view taken along A-A′ of FIG. 12, according to one or more embodiments of the present disclosure;

FIG. 14 is a cross-sectional view taken along B-B′ of FIG. 12, according to one or more embodiments of the present disclosure;

FIG. 15 is an enlarged diagram of part P3 of FIG. 13, according to one or more embodiments of the present disclosure;

FIGS. 16 to 25 are cross-sectional views illustrating a method for manufacturing a semiconductor device, according to one or more embodiments of the present disclosure;

FIG. 26 is a plan view of a semiconductor device, according to one or more embodiments of the present disclosure;

FIG. 27 is a cross-sectional view taken along A-A′ of FIG. 26, according to one or more embodiments of the present disclosure;

FIG. 28 is an enlarged diagram of part P4 of FIG. 27, according to one or more embodiments of the present disclosure; and

FIGS. 29 to 34 are diagrams illustrating a method for manufacturing a semiconductor device, according to one or more embodiments of the present disclosure, and are cross-sectional views corresponding to A-A′ of FIG. 26.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to”another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “AlₓZn_{y}Sn_{z}O”, “CH₄”, “C₂H₂”, “C₃H₆”, “CoSi”, “GaₓZn_{y}Sn_{z}O”, “HfₓIn_{y}Zn_{z}O”, “InₓGa_{y}O”, “InₓGa_{y}Si_{z}O”, “InₓGa_{y}Zn_{z}O”, “InₓSn_{y}Zn_{z}O”, “InₓZn_{y}O”, “IrOₓ”, “MoCₓ”, “NbN”, “NiSi”, “RuOₓ”, “RuTiN”, “Si₃N₄”, “SiO₂”, “SiOₓN_{y}”, “SnₓO”, “TaN”, “TaSi”, “TaSiN”, “TiAl”, “TiAlN”, “TiN”, “TiSi”, “TiSiN”, “WN”, “YbₓGa_{y}Zn_{z}O”, “ZnₓO”, “ZnₓO_{y}N”, “ZnₓSn_{y}O”, “ZrₓZn_{y}Sn_{z}O”, and the like may refer to a material made of elements included in each of the terms and is not a chemical formula representing a stoichiometric relationship.

Hereinafter, various embodiments of the present disclosure are described with reference to the accompanying drawing.

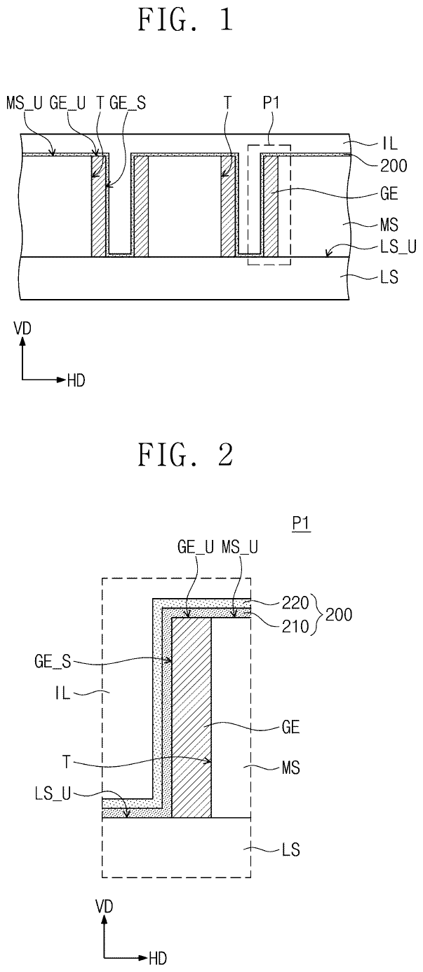

FIG. 1 is a cross-sectional view schematically illustrating a semiconductor device, according to one or more embodiments of the present disclosure. FIG. 2 is an enlarged diagram of part P1 of FIG. 1.

Referring to FIG. 1, a mold structure MS may be disposed on a lower structure LS. The lower structure LS may include a semiconductor substrate, and may include, for example, a silicon (Si) substrate, a germanium (Ge) substrate, a silicon-germanium (Si—Ge) substrate, or a silicon-on-insulator (SOI) substrate. However, the present disclosure is not limited in this regard. The lower structure LS may further include conductive patterns and/or insulating patterns disposed on the semiconductor substrate. The mold structure MS may include a trench T penetrating an inside thereof. The trench T may extend inside the mold structure MS along a vertical direction VD vertical to an upper surface LS_U of the lower structure LS, and may expose the upper surface LS_U of the lower structure LS. The mold structure MS may include, but not be limited to, an insulating material and/or semiconductor material.

Gate electrodes GE may be respectively disposed on inner side surfaces of the trench T, and may extend in the vertical direction VD. The gate electrodes GE may be spaced apart from each other along a horizontal direction HD parallel to the upper surface LS_U of the lower structure LS. The gate electrodes GE may include, but not be limited to, a conductive material, and may include at least one of a metal (e.g., titanium (Ti), molybdenum (Mo), tungsten (W), copper (Cu), aluminum (Al), tantalum (Ta), ruthenium (Ru), iridium (Ir), cobalt (Co), or the like), a metal silicide (e.g., silicide of titanium (Ti), molybdenum (Mo), tungsten (W), copper (Cu), aluminum (Al), tantalum (Ta), ruthenium (Ru), iridium (Ir), cobalt (Co), or the like), or a conductive metal nitride (e.g., nitride of titanium (Ti), molybdenum (Mo), tungsten (W), copper (Cu), aluminum (Al), tantalum (Ta), ruthenium (Ru), iridium (Ir), cobalt (Co), or the like). According to one or more embodiments, the gate electrodes GE may include molybdenum (Mo).

An insulating layer IL may be disposed on the mold structure MS, and may extend into the trench T. The insulating layer IL may cover the gate electrodes GE. The insulating layer IL may partially fill the trench T, and may be interposed between the gate electrodes GE. The insulating layer IL may include an insulating material, and may include at least one of an oxide, a nitride, or an oxynitride (e.g., silicon oxide (SiO₂), silicon nitride (Si₃N₄), or silicon oxynitride (SiOₓN_{y})). According to one or more embodiments, the insulating layer IL may include an oxide (e.g., silicon oxide (SiO₂)).

An anti-oxidation layer 200 may be interposed between each of the gate electrodes GE and the insulating layer IL. The anti-oxidation layer 200 may be interposed between a side surface GE_S of each of the gate electrodes GE and the insulating layer IL, and between an upper surface GE_U of each of the gate electrodes GE and the insulating layer IL. The anti-oxidation layer 200 may be interposed between the upper surface LS_U of the lower structure LS and the insulating layer IL, and an upper surface MS_U of the mold structure MS and the insulating layer IL.

The anti-oxidation layer 200 may include carbon (C). The anti-oxidation layer 200 may further include a metal. According to one or more embodiments, the anti-oxidation layer 200 may include a metal carbide. The anti-oxidation layer 200 may include the same metal as the gate electrodes GE. For example, the anti-oxidation layer 200 may include molybdenum carbide (MoCₓ). According to one or more embodiments, the anti-oxidation layer 200 may further include an impurity, and the impurity may include at least one of silicon (Si), oxygen (O), or nitrogen (N).

Referring to FIG. 2, according to one or more embodiments, the anti-oxidation layer 200 may include a first layer 210 between each of the gate electrodes GE and the insulating layer IL, and a second layer 220 between the first layer 210 and the insulating layer IL. The first layer 210 and the second layer 220 may be interposed between a side surface GE_S of each of the gate electrodes GE and the insulating layer IL, and between the upper surface GE_U of each of the gate electrodes GE and the insulating layer IL. The first layer 210 may be interposed between the side surface GE_S of each of the gate electrodes GE and the second layer 220, and between the upper surface GE_U of each of the gate electrodes GE and the second layer 220. The first layer 210 and the second layer 220 may also be interposed between the upper surface LS_U of the lower structure LS and the insulating layer IL, and between the upper surface MS_U of the mold structure MS and the insulating layer IL. In such a case, the first layer 210 may be interposed between the upper surface LS_U of the lower structure LS and the second layer 220, and between the upper surface MS_U of the mold structure MS and the second layer 220.

The first layer 210 may include a metal and/or carbon (C). For example, the first layer 210 may include a metal carbide. The first layer 210 may include the same metal as the gate electrodes GE. For example, the first layer 210 may include molybdenum carbide (MoCₓ). The second layer 220 may include carbon (C). The second layer 220 may have a smaller metal content than the first layer 210.

Referring back to FIG. 1, according to the present disclosure, since the anti-oxidation layer 200 is interposed between each of the gate electrodes GE and the insulating layer IL, the gate electrodes GE may be prevented from being oxidized during formation of the insulating layer IL, and/or oxidation of the insulating layer IL may be reduced when compared to a related semiconductor device. Accordingly, resistance of the gate electrodes GE may be prevented from increasing and/or the increase in resistance of the gate electrodes GE may be reduced when compared to a related semiconductor device. According to one or more embodiments, the gate electrodes GE may include a metal (e.g., molybdenum (Mo)). In such a case, conductivity of the gate electrodes GE may be increased. The anti-oxidation layer 200 may include carbon (C), and may further include the same metal as the gate electrodes GE. The anti-oxidation layer 200 may include a metal carbide (e.g., molybdenum carbide (MoCₓ)). Since the anti-oxidation layer 200 including carbon (C) is formed on surfaces of the gate electrodes GE, oxidation of the gate electrodes GE may be suppressed and/or prevented during formation of the insulating layer IL, and as a result, resistance of the gate electrodes GE may be suppressed and/or prevented from increasing. Accordingly, electrical characteristics of transistors including the gate electrodes GE may be improved, when compared to related semiconductor devices.

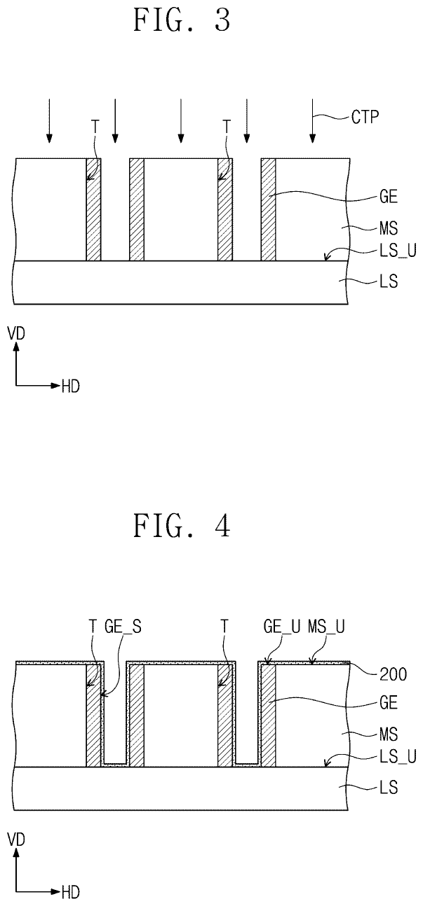

FIGS. 3 and 4 are cross-sectional views schematically illustrating a method for manufacturing the semiconductor device, according to one or more embodiments of the present disclosure. The semiconductor device described with reference to FIGS. 3 and 4 may include and/or may be similar in many respects to the semiconductor described above with reference to FIGS. 1 and 2, and may include additional features not mentioned above. Consequently, repeated descriptions of the semiconductor device of FIGS. 3 and 4 described above with reference to FIGS. 1 and 2 may be omitted for the sake of brevity.

Referring to FIG. 3, the mold structure MS may be formed on the lower structure LS. The trench T may be formed in the mold structure MS. The trench T may extend into the mold structure MS along the vertical direction VD, and may expose the upper surface LS_U of the lower structure LS. For example, forming the trench T may include forming, on the mold structure MS, a mask pattern exposing a region in which the trench T is formed, and etching the mold structure MS using the mask pattern as an etching mask. Subsequent to the trench T being formed, the mask pattern may be removed.

The gate electrodes GE may be respectively formed on the inner side surfaces of the trench T. For example, forming the gate electrodes GE may include forming a gate electrode layer conformally covering an inner surface of the trench T on the mold structure MS, and anisotropically etching the gate electrode layer. The gate electrodes GE may extend in the vertical direction VD, and may be spaced apart from each other along the horizontal direction HD.

A carbon treatment process (CTP) may be performed on the mold structure MS and the gate electrodes GE. According to one or more embodiments, the carbon treatment process (CTP) may be and/or may include a plasma treatment process, an ion implantation process, or the like, using a gas that may include a hydrocarbon (e.g., methane (CH₄), ethyne (C₂H₂), propene (C₃H₆), or the like). According to other embodiments, the carbon treatment process (CTP) may be and/or may include a chemical vapor deposition process using an organometallic source such as, but not limited to, di-isopropylamino silane (DIPAS), bis(tertiary-butylamino) silane (BTBAS), or tetraethoxysilane (TEOS). According to other embodiments, the carbon treatment process (CTP) may be and/or may include a chemical vapor deposition process using a carbon-containing precursor (e.g., ethyne (C₂H₂)).

Referring to FIG. 4, the anti-oxidation layer 200 may be formed on the gate electrodes GE and the mold structure MS by the carbon treatment process (CTP). The anti-oxidation layer 200 may be formed on the side surface GE_S and the upper surface GE_U of each of the gate electrodes GE, and may be formed on the upper surface MS_U of the mold structure MS. The anti-oxidation layer 200 may be formed on the upper surface LS_U of the lower structure LS between the gate electrodes GE.

According to one or more embodiments, the carbon treatment process (CTP) may be and/or may include a plasma treatment process, an ion implantation process, or the like, using gas that may include a hydrocarbon (e.g., methane (CH₄), ethyne (C₂H₂), propene (C₃H₆), or the like). In such a case, a carbon radical generated by the carbon treatment process (CTP) may react with surfaces of the mold structure MS and the gate electrodes GE. The carbon radical may react with the upper surface LS_U of the lower structure LS between the gate electrodes GE. Accordingly, the anti-oxidation layer 200 may be formed on the surfaces of the gate electrodes GE and the mold structure MS, and on the upper surface LS_U of the lower structure LS between the gate electrodes GE. The anti-oxidation layer 200 may include carbon (C) and metal, and may include the same metal as the gate electrodes GE. The anti-oxidation layer 200 may include a metal carbide.

According to other embodiments, the carbon treatment process (CTP) may be and/or may include a chemical vapor deposition process using an organometallic source such as, but not limited to, di-isopropylamino silane (DIPAS), bis(tertiary-butylamino) silane (BTBAS), or tetraethoxysilane (TEOS). In such a case, the organometallic source may be adsorbed onto the surfaces of the mold structure MS and the gate electrodes GE during the carbon treatment process (CTP), and may be adsorbed onto the upper surface LS_U of the lower structure LS between the gate electrodes GE. The adsorbed organometallic source may react with the surfaces of the mold structure MS and the gate electrodes GE, and may react with the upper surface LS_U of the lower structure LS between the gate electrodes GE. Accordingly, the anti-oxidation layer 200 may be formed on the surfaces of the mold structure MS and the gate electrodes GE, and on the upper surface LS_U of the lower structure LS between the gate electrodes GE. During the carbon treatment process (CTP), thermal decomposition and/or plasma treatment may be performed on the anti-oxidation layer 200. The anti-oxidation layer 200 may include carbon (C) and a metal, and may include the same metal as the gate electrodes GE. The anti-oxidation layer 200 may include a metal carbide. The anti-oxidation layer 200 may further include an impurity, and the impurity may include at least one of silicon (Si), oxygen (O), or nitrogen (N).

According to other embodiments, the carbon treatment process (CTP) may be and/or may include a chemical vapor deposition process using a carbon-containing precursor (e.g., ethyne (C₂H₂)). In such a case, during the carbon treatment process (CTP), a carbon (C) layer may be deposited on the surfaces of the mold structure MS and the gate electrodes GE, and may also be deposited on the upper surface LS_U of the lower structure LS between the gate electrodes GE. The carbon (C) layer may at least partially react with the surfaces of the mold structure MS and the gate electrodes GE, and may react with the upper surface LS_U of the lower structure LS between the gate electrodes GE. Accordingly, as described with reference to FIG. 2, the anti-oxidation layer 200 may include the first layer 210 adjacent to the upper surface MS_U of the mold structure MS, the upper surface GE_U and the side surface GE_S of each of the gate electrodes GE, and the upper surface LS_U of the lower structure LS between the gate electrodes GE, and the second layer 220 on the first layer 210. The first layer 210 may include a metal and/or carbon (C), and may include the same metal as the gate electrodes GE. For example, the first layer 210 may include a metal carbide. The second layer 220 may include carbon (C), and may have a smaller metal content than the first layer 210.

Referring back to FIG. 1, the insulating layer IL may be formed on the anti-oxidation layer 200. The insulating layer IL may be formed so as to cover the mold structure MS and the gate electrodes GE, and so as to fill spaces between the gate electrodes GE. For example, the insulating layer IL may be formed in a chemical vapor deposition process. The anti-oxidation layer 200 may be interposed between the side surface GE_S of each of the gate electrodes GE and the insulating layer IL, between the upper surface GE_U of each of the gate electrodes GE and the insulating layer IL, between the upper surface LS_U of the lower structure LS and the insulating layer IL, and between the upper surface MS_U of the mold structure MS and the insulating layer IL.

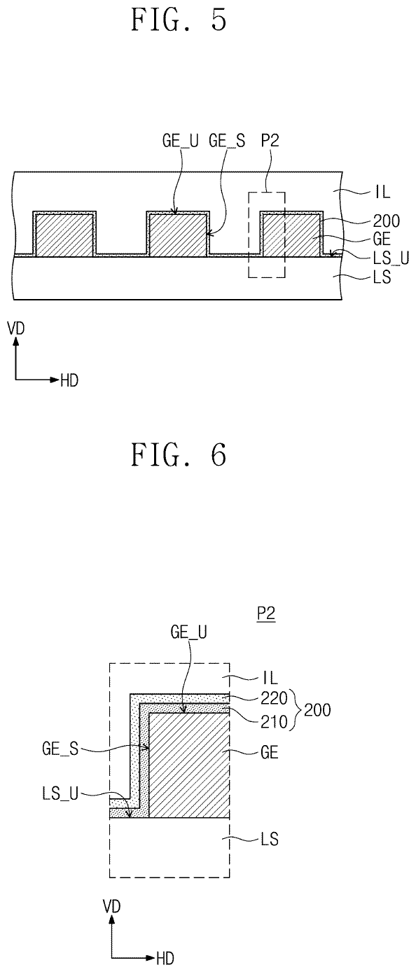

FIG. 5 is a cross-sectional view schematically illustrating the semiconductor device, according to one or more embodiments of the present disclosure. FIG. 6 is an enlarged diagram of part P2 of FIG. 5. The semiconductor device described with reference to FIGS. 5 and 6 may include and/or may be similar in many respects to the semiconductor described above with reference to FIGS. 1 and 2, and may include additional features not mentioned above. Consequently, repeated descriptions of the semiconductor device of FIGS. 5 and 6 described above with reference to FIGS. 1 and 2 may be omitted for the sake of brevity.

Referring to FIG. 5, the gate electrodes GE may be disposed on the lower structure LS. The gate electrodes GE may be spaced apart from each other along the horizontal direction HD parallel to the upper surface LS_U of the lower structure LS.

The insulating layer IL may be disposed on the lower structure LS, and may cover the gate electrodes GE. The insulating layer IL may fill spaces between the gate electrodes GE.

The anti-oxidation layer 200 may be interposed between each of the gate electrodes GE and the insulating layer IL. The anti-oxidation layer 200 may be interposed between the side surface GE_S of each of the gate electrodes GE and the insulating layer IL, and between the upper surface GE_U of each of the gate electrodes GE and the insulating layer IL. The anti-oxidation layer 200 may be interposed between the upper surface LS_U of the lower structure LS between the gate electrodes GE and the insulating layer IL.

Referring to FIG. 6, according to one or more embodiments, the anti-oxidation layer 200 may include the first layer 210 between each of the gate electrodes GE and the insulating layer IL, and the second layer 220 between the first layer 210 and the insulating layer IL. The first layer 210 and the second layer 220 may be interposed between the side surface GE_S of each of the gate electrodes GE and the insulating layer IL, and between the upper surface GE_U of each of the gate electrodes GE and the insulating layer IL. The first layer 210 may be interposed between the side surface GE_S of each of the gate electrodes GE and the second layer 220, and between the upper surface GE_U of each of the gate electrodes GE and the second layer 220. The first layer 210 and the second layer 220 may also be interposed between the upper surface LS_U of the lower structure LS and the insulating layer IL. In such a case, the first layer 210 may be interposed between the upper surface LS_U of the lower structure LS and the second layer 220.

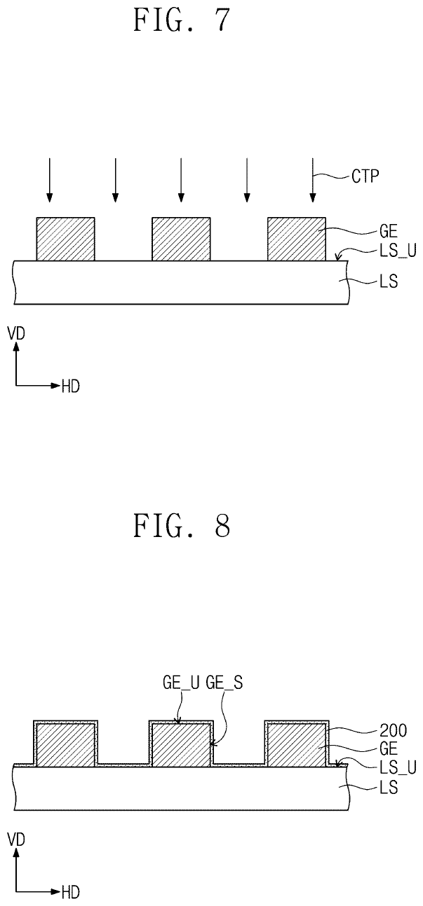

FIGS. 7 and 8 are cross-sectional views schematically illustrating the method for manufacturing the semiconductor device, according to one or more embodiments of the present disclosure. The semiconductor device described with reference to FIGS. 7 and 8 may include and/or may be similar in many respects to the semiconductor described above with reference to FIGS. 3 and 4, and may include additional features not mentioned above. Consequently, repeated descriptions of the semiconductor device of FIGS. 7 and 8 described above with reference to FIGS. 3 and 4 may be omitted for the sake of brevity.

Referring to FIG. 7, the gate electrodes GE may be formed on the lower structure LS. For example, forming the gate electrodes GE may include depositing a gate electrode layer on the lower structure LS, and patterning the gate electrode layer. The gate electrodes GE may be spaced apart from each other along the horizontal direction HD.

The carbon treatment process (CTP) may be performed on the gate electrodes GE. The carbon treatment process (CTP) may be substantially similar and/or the same as the carbon treatment process (CTP) described with reference to FIGS. 3 and 4.

Referring to FIG. 8, the anti-oxidation layer 200 may be formed on the gate electrodes GE in the carbon treatment process (CTP). The anti-oxidation layer 200 may be formed on the side surface GE_S and the upper surface GE_U of each of the gate electrodes GE. The anti-oxidation layer 200 may be formed on the upper surface LS_U of the lower structure LS between the gate electrodes GE. The anti-oxidation layer 200 may be formed in a substantially similar and/or the same method as the anti-oxidation layer 200 described with reference to FIGS. 3 and 4.

Referring back to FIG. 5, the insulating layer IL may be formed on the anti-oxidation layer 200. The insulating layer IL may be formed so as to cover the gate electrodes GE, and so as to fill spaces between the gate electrodes GE. The anti-oxidation layer 200 may be interposed between the side surface GE_S of each of the gate electrodes GE and the insulating layer IL, between the upper surface GE_U of each of the gate electrodes GE and the insulating layer IL, and between the upper surface LS_U of the lower structure LS and the insulating layer IL.

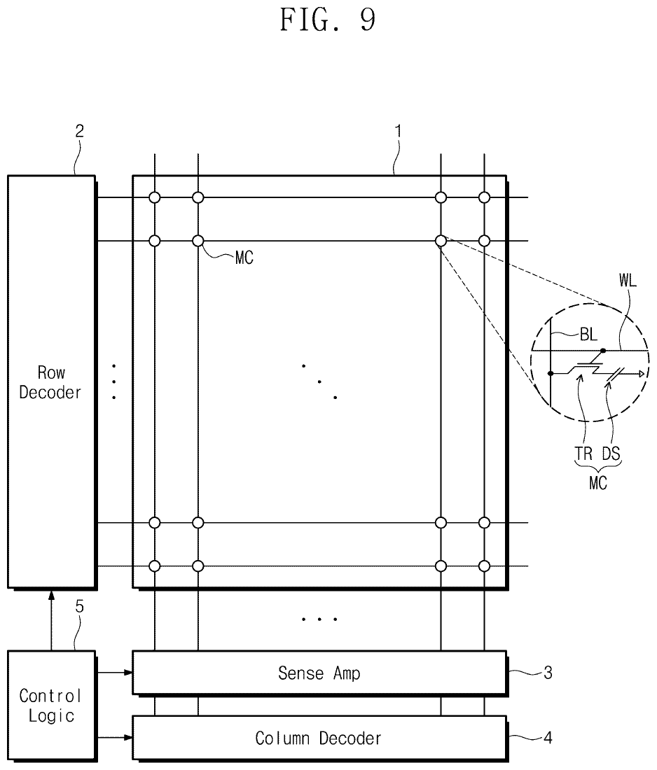

FIG. 9 is a block diagram illustrating the semiconductor device, according to one or more embodiments of the present disclosure.

Referring to FIG. 9, the semiconductor device may include a memory cell array 1, a row decoder 2, a sense amplifier 3, a column decoder 4, and a control logic 5.

The memory cell array 1 may include a plurality of memory cells MC two-dimensionally or three-dimensionally arranged. Each of the memory cells MC may be connected between a word line WL and a bit line BL crossing each other. Each of the memory cells MC may include a selection element TR and a data storage element DS. The selection element TR and the data storage element DS may be electrically connected to each other. The selection element TR may be connected to the word line WL and the bit line BL, and may be provided to a point at which the word line WL and the bit line BL cross each other.

The selection element TR may include a field effect transistor (FET). The data storage element DS may include a capacitor, a magnetic tunnel junction (MTJ) pattern, or a variable resistor. When the selection element TR includes the FET, a gate terminal of the transistor may be connected to the word line WL, and source/drain terminals of the transistor may be respectively connected the bit line BL and the data storage element DS.

The row decoder 2 may select any one of the word lines WL of the memory cell array 1 by decoding an address input from the outside thereof. The address decoded by the row decoder 2 may be provided to a row driver, and the row driver may provide the selected word line WL and the unselected word lines WL with a predetermined voltage in response to control of control circuits.

The sense amplifier 3 may sense and amplify a voltage difference between the selected bit line BL and a standard bit line according to the address decoded by the column decoder 4, and may output the voltage difference.

The column decoder 4 may provide a data transfer path between the sense amplifier 3 and an external element (e.g., a memory controller). The column decoder 4 may select any one among the bit lines BL of the memory cell array 1 by decoding the address input from the outside thereof. The control logic 5 may generate a control signal that controls an operation of writing a data to the memory cell array 1 or reading the data from the memory cell array 1.

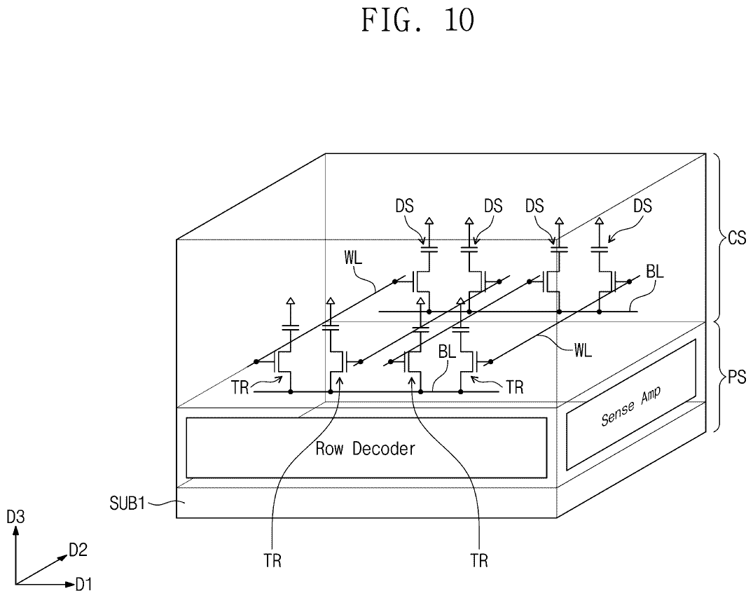

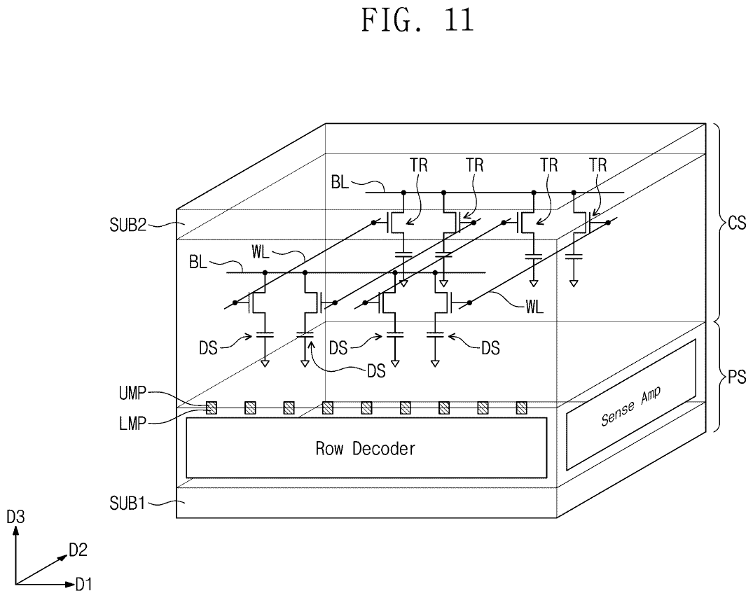

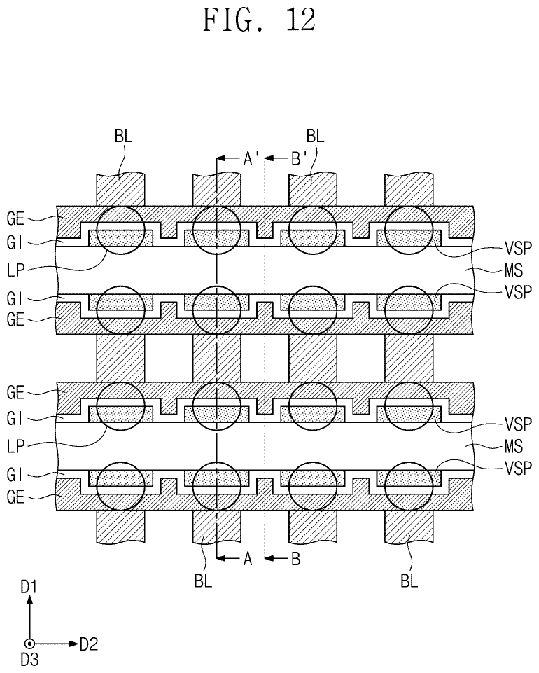

FIGS. 10 and 11 are perspective views briefly illustrating a semiconductor device, according to one or more embodiments of the present disclosure.

Referring to FIGS. 10 and 11, the semiconductor device may include a peripheral circuit structure PS on a first substrate SUB1 and a cell array structure CS on the peripheral circuit structure PS. As used herein, a first direction D1 and a second direction D2 may refer to directions parallel to an upper surface of the first substrate SUB1, and crossing each other, and a third direction D3 may refer to a direction vertical to the upper surface of the first substrate SUB1. The peripheral circuit structure PS and the cell array structure CS may be stacked on the first substrate SUB1 in the third direction D3.

The peripheral circuit structure PS may include core and peripheral circuits formed on the first substrate SUB1. The core and peripheral circuits may include the row decoder 2, the column decoder 4, the sense amplifier 3, and the control logics 5 described with reference to FIG. 9.

The cell array structure CS may include the memory cell array 1 including the memory cells MC two-dimensionally or three-dimensionally arranged. For example, the selection element TR of each of the memory cells MC may include a vertical channel transistor (VCT). The vertical channel transistor (VCT) may include a channel pattern extending long in the third direction D3.

Referring to FIG. 10, according to one or more embodiments, the peripheral circuit structure PS may be disposed between the first substrate SUB1 and the cell array structure CS, and may be electrically connected to the cell array structure through conductive contacts.

Referring to FIG. 11, according to one or more embodiments, the semiconductor device may have a chip-to-chip bonding structure. For example, the peripheral circuit structure PS may be provided on the first substrate SUB1, and first metal pads LMP may be disposed on the peripheral circuit structure PS. The first metal pads LMP may be electrically connected to the core and peripheral circuits. The cell array structure CS may be provided on a second substrate SUB2. Second metal pads UMP may be provided under the cell array structure CS. The second metal pads UMP may be electrically connected to the memory cell array 1. The first metal pads LMP in the peripheral circuit structure PS and the second metal pads UMP of the cell array structure CS may be directly bonded to each other. The peripheral circuit structure PS and the cell array structure CS may be electrically connected to each other through the first and second metal pads LMP and UMP.

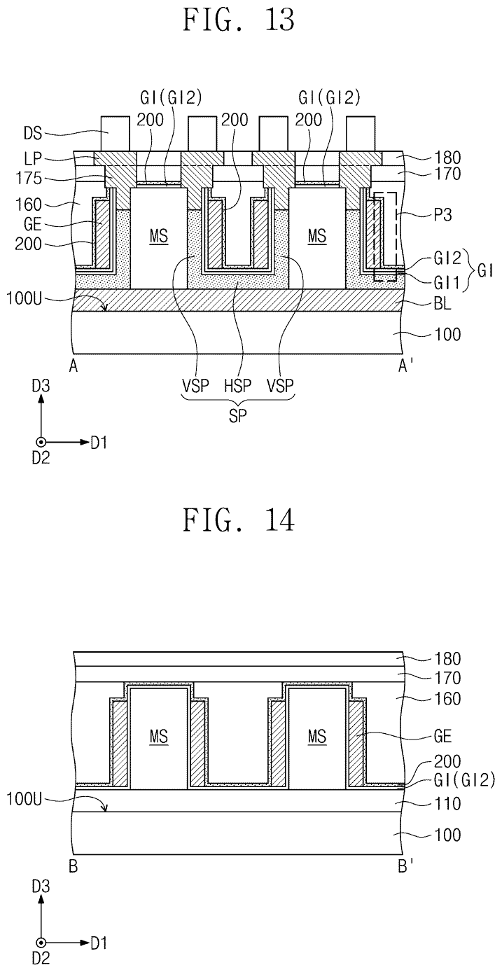

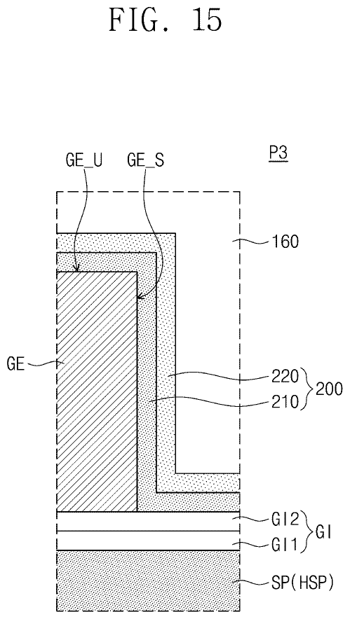

FIG. 12 is a plan view of a semiconductor device, according to one or more embodiments of the present disclosure. FIG. 13 is a cross-sectional view taken along A-A′ of FIG. 12, according to one or more embodiments of the present disclosure. FIG. 14 is a cross-sectional view taken along B-B′ of FIG. 12, according to one or more embodiments of the present disclosure. FIG. 15 is an enlarged diagram of part P3 of FIG. 13, according to one or more embodiments of the present disclosure.

Referring to FIGS. 12 to 14, the cell array structure CS described with reference to FIGS. 10 and 11 may be disposed on a substrate 100. According to one or more embodiments, the substrate 100 may include the peripheral circuit structure PS and the first substrate SUB1 of FIG. 10, and may further include an insulating layer covering the peripheral circuit structure PS. The cell array structure CS may be disposed on the insulating layer. According to other embodiments, the substrate 100 may include the second substrate SUB2 of FIG. 11, and may further include an insulating layer on the second substrate SUB2. The cell array structure CS may be disposed on the insulating layer.

Hereinafter, components of the cell array structure CS are described.

Bit lines BL may be disposed on the substrate 100. The bit lines BL may extend in the first direction D1, and may be spaced apart from each other in the second direction D2. The first direction D1 and the second direction D2 may be parallel to the upper surface 100U of the substrate 100, and may cross (e.g., be vertical to) each other. Insulating patterns 110 may be interposed between the bit lines BL, and may extend between the bit lines BL in the first direction D1. The bit lines BL may include a conductive material. For example, the bit lines BL may include at least one of a doped semiconductor material (e.g., doped silicon, doped germanium, or the like), a metal (e.g., titanium (Ti), molybdenum (Mo), tungsten (W), copper (Cu), aluminum (Al), tantalum (Ta), ruthenium (Ru), iridium (Ir), cobalt (Co), or the like), a metal silicide (e.g., a silicide of titanium (Ti), molybdenum (Mo), tungsten (W), copper (Cu), aluminum (Al), tantalum (Ta), ruthenium (Ru), iridium (Ir), cobalt (Co), or the like), or a conductive metal nitride (e.g., a nitride of titanium (Ti), molybdenum (Mo), tungsten (W), copper (Cu), aluminum (Al), tantalum (Ta), ruthenium (Ru), iridium (Ir), cobalt (Co), or the like). According to one or more embodiments, the bit lines BL may include a carbon-based two-dimensional (2D) material (e.g., graphene), a carbon-based three-dimensional (3D) material (e.g., carbon nanotube), or a combination thereof. The insulating patterns 110 may include an insulating material (e.g., silicon oxide (SiO₂), silicon nitride (Si₃N₄), silicon oxynitride (SiOₓN_{y}), or the like).

Mold structures MS may be disposed on the bit lines BL and the insulating patterns 110, and may cross the bit lines BL and the insulating patterns 110. The mold structures MS may extend in the second direction D2, and may be spaced apart from each other in the first direction D1. The mold structures MS may include an insulating material (e.g., silicon oxide (SiO₂), silicon nitride (Si₃N₄), silicon oxynitride (SiOₓN_{y}), or the like).

The semiconductor pattern SP may be disposed on each of the bit lines BL, and between the mold structures MS. The semiconductor pattern SP may include vertical semiconductor patterns VSP respectively disposed on side surfaces of the mold structures MS, and a horizontal semiconductor pattern HSP disposed between the mold structures MS. The horizontal semiconductor pattern HSP may be disposed on an upper surface of each of the bit lines BL, and may extend in the first direction D1 to be connected to lower portions of the vertical semiconductor patterns VSP. The vertical semiconductor patterns VSP and the horizontal semiconductor pattern HSP may be in contact with each other without a boundary surface, and may be integrally connected to each other. The semiconductor pattern SP may have a U shape on one cross-sectional view.

According to one or more embodiments, the semiconductor pattern SP may include oxide semiconductor. For example, the oxide semiconductor may include indium gallium zinc oxide (InₓGa_{y}Zn_{z}O), indium gallium silicon oxide (InₓGa_{y}Si_{z}O), indium tin zinc oxide (InₓSn_{y}Zn_{z}O), indium zinc oxide (InₓZn_{y}O), zinc oxide (ZnₓO), zinc tin oxide (ZnₓSn_{y}O), zinc oxynitride (ZnₓO_{y}N), zirconium zinc tin oxide (ZrₓZn_{y}Sn_{z}O), tin oxide (SnₓO), hafnium indium zinc oxide (HfₓIn_{y}Zn_{z}O), gallium zinc tin oxide (GaₓZn_{y}Sn_{z}O), aluminum zinc tin oxide (AlₓZn_{y}Sn_{z}O), ytterbium gallium zinc oxide (YbₓGa_{y}Zn_{z}O), or indium gallium oxide (InₓGa_{y}O), or a combination thereof. For example, the semiconductor pattern SP may include indium-gallium-zinc oxide (IGZO). The semiconductor pattern SP may include a single-layer or multiple layer of the oxide semiconductor, and may include the oxide semiconductor being amorphous, crystalline, or polycrystalline. The semiconductor pattern SP may have a greater band-gap energy than silicon (Si). For example, the semiconductor pattern SP may have a band-gap energy of about 1.5 electron-volt (eV) to about 5.6 eV. For example, the semiconductor pattern SP may have a band-gap energy of about 2.0 eV to about 4.0 eV.

According to one or more embodiments, the semiconductor pattern SP may include a semiconductor material, and may include, for example, at least one of silicon (e.g., single-crystalline silicon), germanium (Ge), or silicon-germanium (Si—Ge). According to one or more embodiments, the semiconductor pattern SP may include a two-dimensional (2D) semiconductor material (e.g., graphene), a three-dimensional (3D) semiconductor material (e.g., carbon nanotube), or a combination thereof.

Gate electrodes GE may be disposed on the bit lines BL and the insulating patterns 110, and between the mold structures MS. The gate electrodes GE may cross the bit lines BL and the insulating patterns 110. The gate electrodes GE may extend in the second direction D2, and may be spaced apart from each other in the first direction D1. The gate electrodes GE may be referred to as word lines. A pair of gate electrodes GE among the gate electrodes GE may be disposed between the mold structures MS and on the semiconductor pattern SP. The pair of gate electrodes GE may be respectively disposed on side surfaces of the mold structures MS, and may be spaced apart from each other on the horizontal semiconductor pattern HSP in the first direction D1. Each of the vertical semiconductor patterns VSP may be interposed between the corresponding gate electrode GE of the pair of gate electrodes GE and a side surface of the corresponding mold structure MS of the mold structure MS.

The gate electrodes GE may include a conductive material, and may include at least one of metal (e.g., titanium (Ti), molybdenum (Mo), tungsten (W), copper (Cu), aluminum (Al), tantalum (Ta), ruthenium (Ru), iridium (Ir), cobalt (Co), or the like), metal silicide (e.g., silicide of titanium (Ti), molybdenum (Mo), tungsten (W), copper (Cu), aluminum (Al), tantalum (Ta), ruthenium (Ru), iridium (Ir), cobalt (Co), or the like), or conductive metal nitride (e.g., nitride of titanium (Ti), molybdenum (Mo), tungsten (W), copper (Cu), aluminum (Al), tantalum (Ta), ruthenium (Ru), iridium (Ir), cobalt (Co), or the like). According to one or more embodiments, the gate electrodes GE may include molybdenum (Mo).

A gate insulating pattern GI may be interposed between the side surface of each of the mold structures MS and each of the gate electrodes GE. The gate insulating pattern GI may extend between each of the vertical semiconductor patterns VSP and each of the gate electrodes GE. The gate insulating pattern GI may extend between each of the gate electrodes GE and the horizontal semiconductor pattern HSP, and between each of the gate electrodes GE and each of the insulating patterns 110.

The gate insulating pattern GI may include a first gate insulating pattern GI1 and a second gate insulating pattern GI2. The first gate insulating pattern GI1 may be interposed between each of the vertical semiconductor patterns VSP and each of the gate electrodes GE, and may extend between each of the gate electrodes GE and the horizontal semiconductor pattern HSP. The second gate insulating pattern GI2 may be interposed between each of the gate electrodes GE and the first gate insulating pattern GI1, and may extend between the side surface of each of the mold structures MS and each of the gate electrodes GE. The second gate insulating pattern GI2 may extend between each of the insulating patterns 110 and each of the gate electrodes GE, and may further extend onto an upper surface of each of the mold structures MS.

For example, the gate insulating pattern GI may include at least one of a silicon oxide (SiO₂) or a high-dielectric material. As used herein, the high-dielectric material may refer to a material having a greater dielectric constant than silicon oxide (SiO₂).

A buried insulating layer 160 may be interposed between the mold structures MS, and may cover upper surfaces and side surfaces of the gate electrodes GE. The buried insulating layer 160 may be interposed between the pair of gate electrodes GE, and may extend onto the upper surfaces of the pair of gate electrodes GE. The gate insulating pattern GI may extend between each of the mold structures MS and the buried insulating layer 160. The gate insulating pattern GI may extend between the horizontal semiconductor pattern HSP and the buried insulating layer 160, and between each of the insulating patterns 110 and the buried insulating layer 160. The buried insulating layer 160 may include an insulating material, and may include at least one of an oxide, a nitride, or an oxynitride (e.g., silicon oxide (SiO₂), silicon nitride (Si₃N₄), or silicon oxynitride (SiOₓN_{y})). According to one or more embodiments, the insulating layer IL may include oxide (e.g., silicon oxide (SiO₂)).

An anti-oxidation layer 200 may be interposed between each of the gate electrodes GE and the buried insulating layer 160. The anti-oxidation layer 200 may be interposed between a side surface of each of the gate electrodes GE and the buried insulating layer 160, and between an upper surface of each of the gate electrodes GE and the buried insulating layer 160. The anti-oxidation layer 200 may be interposed between the horizontal semiconductor pattern HSP and the buried insulating layer 160, and the gate insulating pattern GI may be interposed between the horizontal semiconductor pattern HSP and the anti-oxidation layer 200. The anti-oxidation layer 200 may be interposed between each of the insulating patterns 110 and the buried insulating layer 160, and the gate insulating pattern GI may be interposed between each of the insulating patterns 110 and the anti-oxidation layer 200. The anti-oxidation layer 200 may be interposed between each of the mold structures MS and the buried insulating layer 160, and may extend onto the upper surfaces of the mold structures MS. The gate insulating pattern GI may be interposed between each of the mold structures MS and the anti-oxidation layer 200, and may extend between the upper surface of each of the mold structures MS and the anti-oxidation layer 200.

The anti-oxidation layer 200 may include carbon (C). The anti-oxidation layer 200 may further include a metal. According to one or more embodiments, the anti-oxidation layer 200 may include a metal carbide. The anti-oxidation layer 200 may include the same metal as the gate electrodes GE. For example, the anti-oxidation layer 200 may include molybdenum carbide (MoCₓ). According to one or more embodiments, the anti-oxidation layer 200 may further include an impurity, and the impurity may include at least one of silicon (Si), oxygen (O), or nitrogen (N).

Referring to FIGS. 13 and 15, according to one or more embodiments, the anti-oxidation layer 200 may include the first layer 210 between each of the gate electrodes GE and the buried insulating layer 160, and the second layer 220 between the first layer 210 and the buried insulating layer 160. The first layer 210 and the second layer 220 may be interposed between the side surface GE_S of each of the gate electrodes GE and the buried insulating layer 160, and between the upper surface GE_U of each of the gate electrodes GE and the buried insulating layer 160. The first layer 210 may be interposed between the side surface GE_S of each of the gate electrodes GE and the second layer 220, and between the upper surface GE_U of each of the gate electrodes GE and the second layer 220. The first layer 210 and the second layer 220 may be interposed between the gate insulating pattern GI and the buried insulating layer 160 between the pair of gate electrodes GE. The first layer 210 may be interposed between the gate insulating pattern GI and the second layer 220.

The first layer 210 may include a metal and/or carbon (C). For example, the first layer 210 may include a metal carbide. The first layer 210 may include the same metal as the gate electrodes GE. For example, the first layer 210 may include molybdenum carbide (MoCₓ). The second layer 220 may include carbon (C). The second layer 220 may have a smaller metal content than the first layer 210.

Referring back to FIGS. 12 to 14, a first upper insulating layer 170 may be disposed on the mold structures MS and the buried insulating layer 160. The first upper insulating layer 170 may cover the anti-oxidation layer 200 on the upper surfaces of the mold structures MS, and may cover an upper surface of the buried insulating layer 160. A second upper insulating layer 180 may be disposed on the first upper insulating layer 170, and may cover an upper surface of the first upper insulating layer 170. The first and second upper insulating layers 170 and 180 may include a silicon oxide (SiO₂) layer, a silicon nitride (Si₃N₄) layer, a silicon oxynitride (SiOₓN_{y}) layer, and/or a low-dielectric layer.

Node contacts 175 may be respectively disposed on the vertical semiconductor patterns VSP. Each of the node contacts 175 may penetrate the first upper insulating layer 170, the anti-oxidation layer 200 and the gate insulating pattern GI, and may be electrically connected to one corresponding vertical semiconductor pattern VSP thereamong. Each of the node contacts 175 may be in contact with one upper surface of the corresponding one vertical semiconductor patterns VSP thereamong.

Landing pads LP may be respectively disposed on the node contacts 175. Each of the landing pads LP may penetrate the second upper insulating layer 180, and may be electrically connected to each of the node contacts 175. Each of the landing pads LP may be in contact with an upper surface of each of the node contacts 175, and may have various shapes such as, but not limited to, a circle, an ellipsoid, a rectangle, a square, a rhombus, and a hexagon, on a plan view.

The node contacts 175 and the landing pads LP may include a conductive material. For example, the node contacts 175 and the landing pads LP may be composed of at least one of doped polysilicon, aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminide (TiAl), titanium aluminum nitride (TiAlN), titanium silicide (TiSi), titanium silicon nitride (TiSiN), tantalum silicide (TaSi), tantalum silicon nitride (TaSiN), ruthenium titanium nitride (RuTiN), nickel silicide (NiSi), cobalt silicide (CoSi), iridium oxide (IrOₓ), ruthenium oxide (RuOₓ), or a combination thereof. However, the present disclosure is not limited thereto. The node contacts 175 and the landing pads LP may include the same conductive material.

Data storage patterns DS may be respectively disposed on the landing pads LP. The data storage patterns DS may be respectively electrically connected to the vertical semiconductor patterns VSP through the landing pads LP and the node contacts 175. The data storage patterns DS may be arranged so as to be spaced apart from each other along the first direction D1 and the second direction D2. According to one or more embodiments, the data storage patterns DS may be capacitors. In such a case, the data storage patterns DS may include lower electrodes respectively disposed on the landing pads LP, an upper electrode covering the lower electrodes, and a dielectric layer between each of the lower electrodes and the upper electrode. According to other embodiments, the data storage patterns DS may be variable resistance patterns capable of being switched to two (2) resistance states by an electrical pulse. For example, the data storage patterns DS may include a phase-change material changing a crystalline state according to an amount of current, a perovskite compound, transition metal oxide, a magnetic material, a ferromagnetic material or an anti-ferromagnetic material.

According to the present disclosure, since the anti-oxidation layer 200 is interposed between each of the gate electrodes GE and the buried insulating layer 160, the gate electrodes GE may be prevented from being oxidized during formation the buried insulating layer 160, and/or oxidation of the gate electrodes GE may be reduced when compared to a related semiconductor device. Accordingly, resistance of the gate electrodes GE may be prevented from increasing and/or the increase in resistance of the gate electrodes GE may be reduced when compared to a related semiconductor device. According to one or more embodiments, the gate electrodes GE may include a metal (e.g., molybdenum (Mo)). In such a case, the gate electrodes GE may have high conductivity at a relatively small thickness, and thus the gate electrodes GE may be relatively highly integrated. Accordingly, electrical characteristics of vertical channel transistors including the gate electrodes GE may be improved, and the semiconductor device including the vertical channel transistors may be relatively highly integrated.

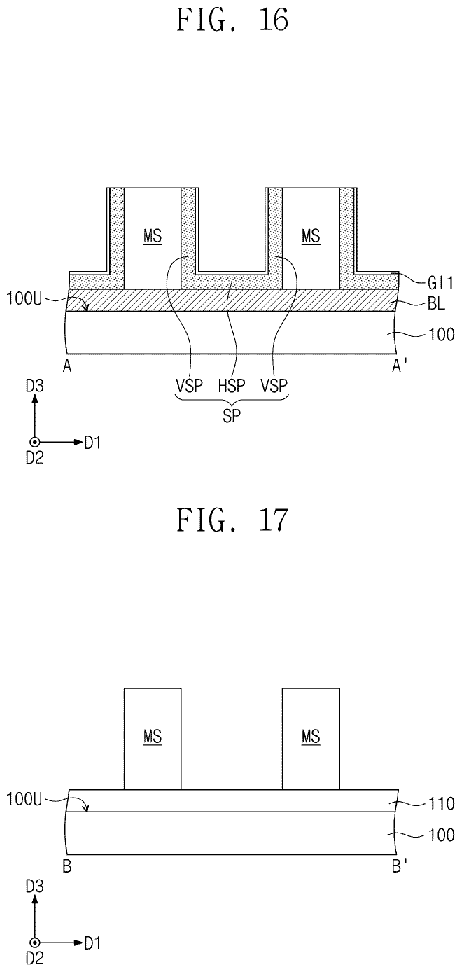

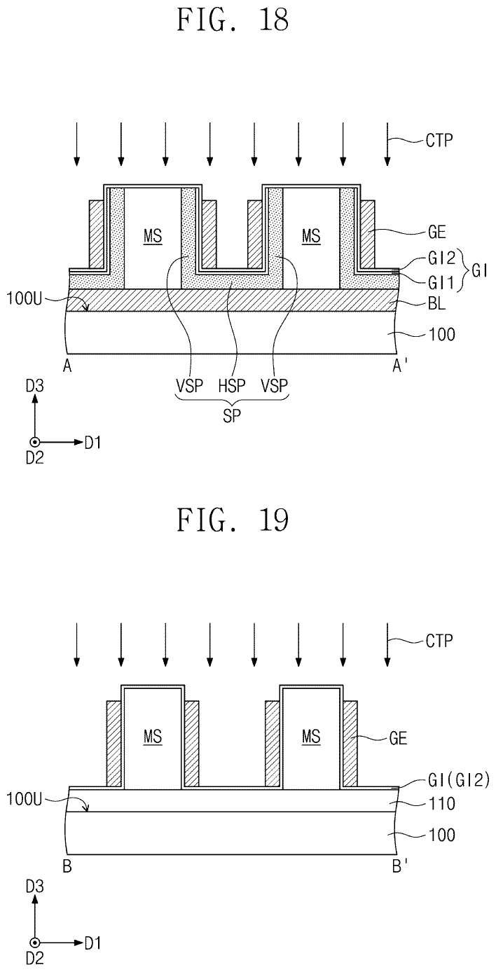

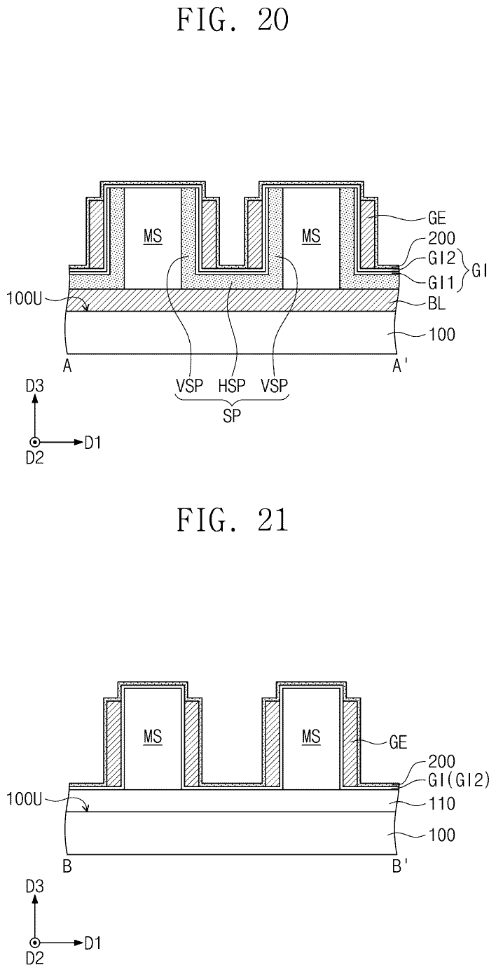

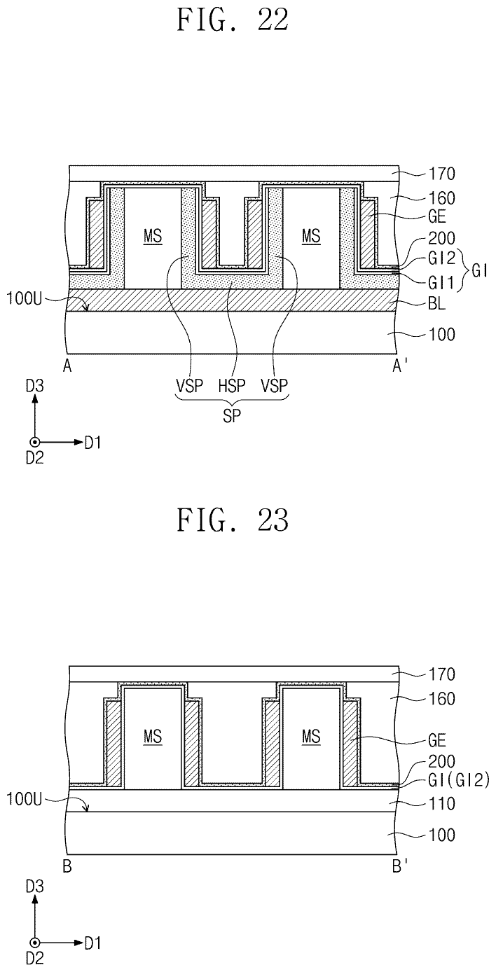

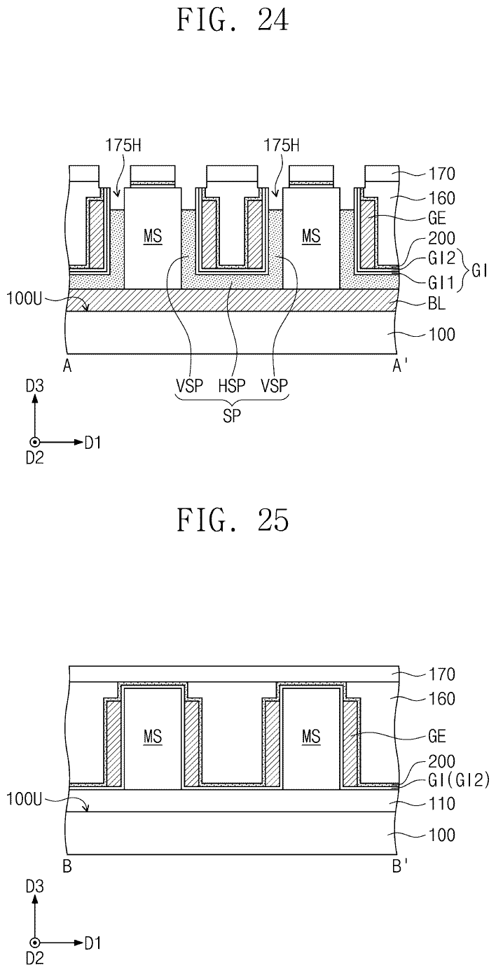

FIGS. 16 to 25 are cross-sectional views illustrating the method for manufacturing the semiconductor device, according to one or more embodiments of the present disclosure. FIGS. 16, 18, 20, 22, and 24 are cross-sectional views corresponding to A-A′ of FIG. 12, according to one or more embodiments of the present disclosure. FIGS. 17, 19, 21, 23, and 25 are cross-sectional views corresponding to B-B′ of FIG. 12, according to one or more embodiments of the present disclosure. The method for manufacturing the semiconductor device described with reference to FIGS. 16 to 25 may include and/or may be similar in many respects to the semiconductor described above with reference to FIGS. 12 to 15, and may include additional features not mentioned above. Consequently, repeated descriptions of the method for manufacturing the semiconductor device of FIGS. 16 to 25 described above with reference to FIGS. 12 to 15 may be omitted for the sake of brevity.

Referring to FIGS. 12, 16, and 17, the bit lines BL may be formed on the substrate 100. For example, forming the bit lines BL may include forming a conductive layer on the substrate 100, and patterning the conductive layer. The bit lines BL may extend in the first direction D1, and may be spaced apart from each other in the second direction D2. The insulating patterns 110 may be formed between the bit lines BL, and may extend between the bit lines BL in the first direction D1. For example, forming the insulating patterns 110 may include forming an insulating layer that covers the bit lines BL and that fills spaces between the bit lines BL, and planarizing the insulating layer until upper surfaces of the bit lines BL are exposed.

The mold structures MS may be formed on the bit lines BL and the insulating patterns 110, and may cross the bit lines BL and the insulating patterns 110. The mold structures MS may extend in the second direction D2, and may be spaced apart from each other in the first direction D1.

The semiconductor pattern SP may be formed on each of the bit lines BL, and between the mold structures MS. The semiconductor pattern SP may include the vertical semiconductor patterns VSP respectively disposed on side surfaces of the mold structures MS, and the horizontal semiconductor pattern HSP disposed between the mold structures MS. The horizontal semiconductor pattern HSP may be disposed on the upper surface of each of the bit lines BL, and may extend in the first direction D1 to be connected to lower portions of the vertical semiconductor patterns VSP. The semiconductor pattern SP may have a U shape on one cross-sectional view.

The first gate insulating pattern GI1 may be formed on the semiconductor pattern SP. The first gate insulating pattern GI1 may cover side surfaces, facing each other, of the vertical semiconductor patterns VSP, and may extend onto the horizontal semiconductor pattern HSP. The first gate insulating pattern GI1 may have a U shape on one cross-sectional view.

For example, forming the semiconductor pattern SP and the first gate insulating pattern GI1 may include forming a semiconductor layer conformally covering the upper surfaces and the side surfaces of the mold structures MS, and covering the upper surfaces of the bit lines BL and the insulating patterns 110 between the mold structures MS, forming a first gate insulating layer on the semiconductor layer, removing the semiconductor layer and the first gate insulating layer on the insulating patterns 110, and planarizing the semiconductor layer and the first gate insulating layer on the bit lines BL until the upper surfaces of the mold structures MS are exposed. For example, removing the semiconductor layer and the first gate insulating layer on the insulating patterns 110 may include removing the semiconductor layer and the first gate insulating layer from the upper surfaces and the side surfaces of the mold structures MS on the insulating patterns 110, and removing the semiconductor layer and the first gate insulating layer from the upper surfaces of the insulating patterns 110 between the mold structures MS. For example, planarizing the semiconductor layer and the first gate insulating layer on the bit lines BL may include removing the semiconductor layer and the first gate insulating layer from the upper surfaces of the mold structures MS on the bit lines BL. Accordingly, the vertical semiconductor patterns VSP may be respectively formed on the side surfaces of the mold structures MS on the bit lines BL, and may be formed on the upper surface of each of the bit lines BL between the mold structures MS. The first gate insulating pattern GI1 may be formed so as to conformally cover the vertical semiconductor patterns VSP and the horizontal semiconductor pattern HSP.

Referring to FIGS. 12, 18, and 19, the second gate insulating pattern GI2 may be formed so as to conformally cover the mold structures MS, and the insulating patterns 110, the semiconductor pattern SP and the first gate insulating pattern GI1 between the mold structures MS. The second gate insulating pattern GI2 may cover the upper surfaces of the mold structures MS. The second gate insulating pattern GI2 may conformally cover the first gate insulating pattern GI1 and the semiconductor pattern SP between the mold structures MS. The second gate insulating pattern GI2 may conformally cover the side surfaces of the mold structures MS on the insulating patterns 110, and may extend onto the upper surfaces of the insulating patterns 110 between the mold structures MS. The first gate insulating pattern GI1 and the second gate insulating pattern GI2 may be referred to as the gate insulating pattern GI.

The gate electrodes GE may be formed on the bit lines BL and the insulating patterns 110, and between the mold structures MS. The gate electrodes GE may cross the bit lines BL and the insulating patterns 110. The gate electrodes GE may extend in the second direction D2, and may be spaced apart from each other in the first direction D1. A pair of gate electrodes GE among the gate electrodes GE may be disposed between the mold structures MS. The pair of gate electrodes GE may be respectively disposed on the side surfaces of the mold structures MS, and may be spaced apart from each other on the horizontal semiconductor pattern HSP in the first direction D1. Each of the vertical semiconductor patterns VSP may be interposed between a corresponding gate electrode GE of the pair of gate electrodes GE and the side surface of a corresponding mold structure MS among the mold structures MS. The gate insulating pattern GI may be interposed between each of the vertical semiconductor patterns VSP and the corresponding gate electrode GE, and may extend between each of the pair of gate electrodes GE and the horizontal semiconductor pattern HSP. The gate insulating pattern GI may extend between the side surface of each of the mold structures MS and each of the pair of gate electrodes GE, and may extend between each of the pair of gate electrodes GE and each of the insulating patterns 110.

For example, forming the gate electrodes GE may include forming a gate electrode layer conformally covering the insulating patterns 110, the gate insulating pattern GI and the semiconductor pattern SP between the mold structure MS, and anisotropically etching the gate electrode layer. The anisotropic etching process may be performed so as to locally leave the gate electrodes GE on the side surfaces of the mold structures MS. For example, forming the gate electrodes GE may further include recessing upper portions of the gate electrodes GE.

A carbon treatment process (CTP) may be performed on the mold structures MS and the gate electrodes GE. The carbon treatment process (CTP) may be substantially similar and/or the same as the carbon treatment process (CTP) described with reference to FIGS. 3 and 4.

Referring to FIGS. 12, 20, and 21, the anti-oxidation layer 200 may be formed on the mold structures MS and the gate electrodes GE by the carbon treatment process (CTP) process. The anti-oxidation layer 200 may be formed on the upper surfaces and the side surfaces of the gate electrodes GE, and may be formed on the gate insulating pattern GI between the pair of gate electrodes GE. The anti-oxidation layer 200 may also be formed on the gate insulating pattern GI on the upper surfaces and the side surfaces of the mold structures MS. The anti-oxidation layer 200 may be formed in a substantially similar and/or the same method as the anti-oxidation layer 200 described with reference to FIGS. 3 and 4.

Referring to FIGS. 12, 22, and 23, the buried insulating layer 160 may be formed so as to fill spaces between the mold structures MS. The buried insulating layer 160 may be interposed between the pair of gate electrodes GE. For example, forming the buried insulating layer 160 may include forming an insulating layer covering the mold structures MS and the gate electrodes GE, and planarizing the insulating layer until the anti-oxidation layer 200 on the upper surfaces of the mold structures MS are exposed. According to the present disclosure, the anti-oxidation layer 200 may prevent and/or suppress surfaces of the gate electrodes GE from being oxidized during formation of the buried insulating layer 160, and thus, resistance of the gate electrodes GE may be prevented and/or suppressed from increasing, when compared to a related semiconductor device.

The first upper insulating layer 170 may be formed on the mold structures MS and the buried insulating layer 160. The first upper insulating layer 170 may cover the anti-oxidation layer 200 on the upper surfaces of the mold structures MS, and may cover the upper surface of the buried insulating layer 160.

Referring to FIGS. 12, 24 and 25, node contact holes 175H may be formed in the first upper insulating layer 170. Each of the node contact holes 175H may penetrate the first upper insulating layer 170, the anti-oxidation layer 200 and the gate insulating pattern GI, and may expose one corresponding vertical semiconductor pattern VSP thereamong. Upper portions, of the vertical semiconductor patterns VSP, exposed by the node contact holes 175H may be recessed, and thus, each of the node contact holes 175H may extend between the side surface of each of the mold structures MS and the gate insulating pattern GI.

Referring back to FIGS. 12, 13, and 14, the node contacts 175 may be respectively formed in the node contact holes 175H, and the landing pads LP may be respectively formed on the node contacts 175. For example, forming the node contacts 175 and the landing pads LP may include forming, on the first upper insulating layer 170, an upper conductive layer that fills the node contact holes 175H and that extends onto the first upper insulating layer 170, and patterning the upper conductive layer. The landing pads LP may be formed by patterning the upper conductive layer. Parts of the upper conductive layer that fill the node contact holes 175H may be referred to as the node contacts 175.

The second upper insulating layer 180 may be formed so as to fill spaces between the landing pads LP. For example, forming the second upper insulating layer 180 may include forming the second upper insulating layer 180 covering the landing pads LP on the first upper insulating layer 170, and planarizing the second upper insulating layer 180 until the upper surfaces of the landing pads LP are exposed. The data storage patterns DS may be respectively formed on the exposed upper surfaces of the landing pads LP.

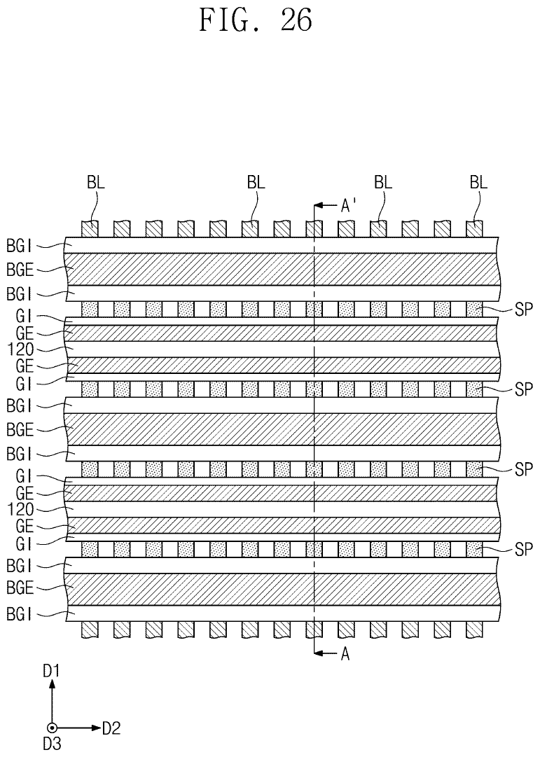

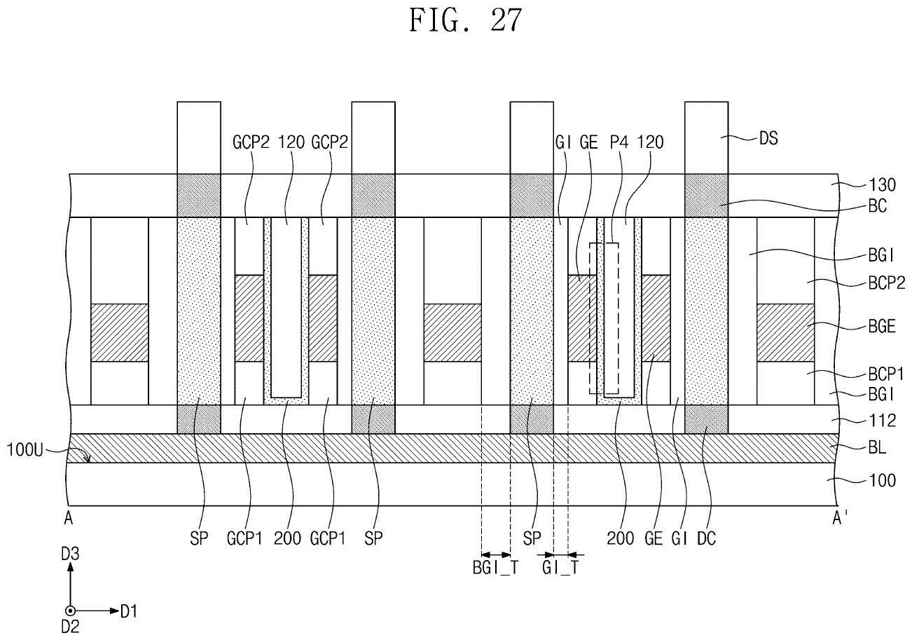

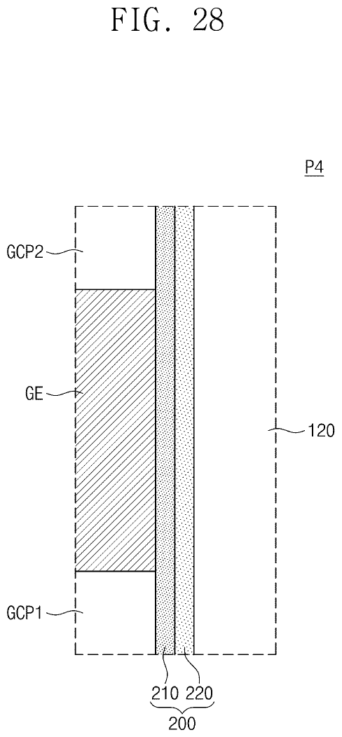

FIG. 26 is a plan view of the semiconductor device, according to one or more embodiments of the present disclosure. FIG. 27 is a cross-sectional view taken along A-A′ of FIG. 26, according to one or more embodiments of the present disclosure. FIG. 28 is an enlarged diagram of part P4 of FIG. 27, according to one or more embodiments of the present disclosure.

Referring to FIGS. 26 and 27, the cell array structure CS described with reference to FIGS. 10 and 11 may be disposed on the substrate 100. According to one or more embodiments, the substrate 100 may include the first substrate SUB1 and the peripheral circuit structure PS of FIG. 10 and may further include an insulating layer covering the peripheral circuit structure PS. The cell array structure CS may be disposed on the insulating layer. According to other embodiments, the substrate 100 may include the second substrate SUB2 of FIG. 11, and may further include an insulating layer on the second substrate SUB2. The cell array structure CS may be disposed on the insulating layer.

Hereinafter, components of the cell array structure CS are described.

Bit lines BL may be disposed on the substrate 100. The bit lines BL may extend in the first direction D1, and may be spaced apart from each other in the second direction D2. The first direction D1 and the second direction D2 may be parallel to the upper surface 100U of the substrate 100, and may cross (e.g., vertical to) each other. Insulating patterns may be interposed between the bit lines BL, and may extend between the bit lines BL in the first direction D1. The bit lines BL may include a conductive material. For example, the bit lines BL may include at least one of a doped semiconductor material (e.g., doped silicon, doped germanium, or the like), a metal (e.g., titanium (Ti), molybdenum (Mo), tungsten (W), copper (Cu), aluminum (Al), tantalum (Ta), ruthenium (Ru), iridium (Ir), cobalt (Co), or the like), a metal silicide (e.g., silicide of titanium (Ti), molybdenum (Mo), tungsten (W), copper (Cu), aluminum (Al), tantalum (Ta), ruthenium (Ru), iridium (Ir), cobalt (Co), or the like), or a conductive metal nitride (e.g., nitride of titanium (Ti), molybdenum (Mo), tungsten (W), copper (Cu), aluminum (Al), tantalum (Ta), ruthenium (Ru), iridium (Ir), cobalt (Co), or the like). The insulating patterns may include an insulating material (e.g., silicon oxide (SiO₂), silicon nitride (Si₃N₄), silicon oxynitride (SiOₓN_{y}), or the like).

Lower conductive contacts DC may be disposed on the bit lines BL, and may be spaced apart from each other in the first direction D1 and the second direction D2. The lower conductive contacts DC, spaced apart from each other in the first direction D1, among the lower conductive contacts DC may be disposed on a corresponding bit line BL among the bit lines BL, and may be spaced apart from each other on the corresponding bit line BL in the first direction D1. The lower conductive contacts DC spaced apart from each other in the first direction D1 may be connected to the corresponding bit line BL in common. The lower conductive contacts DC, spaced apart from each other in the second direction D2, among the lower conductive contacts DC may be respectively disposed on the bit lines BL, and may be respectively connected to the bit lines BL. The lower conductive contacts DC may include a conductive material, and may include, for example, a doped semiconductor material (e.g., doped silicon, doped germanium, or the like).

A lower insulating layer 112 may be disposed on the bit lines BL, and may be interposed between the lower conductive contacts DC. Each of the lower conductive contacts DC may penetrate the lower insulating layer 112 to be connected to a corresponding bit line BL among the bit lines BL. For example, the lower insulating layer 112 may include, but not be limited to, silicon oxide (SiO₂), silicon nitride (Si₃N₄), silicon oxynitride (SiOₓN_{y}), or the like.

According to one or more embodiments, the lower conductive contacts DC spaced apart from each other in the first direction D1 may extend in the first direction D1 to be connected to each other, and may constitute one lower conductive line. In such a case, the lower conductive lines may be respectively disposed on the bit lines BL, and may extend in the first direction D1. The lower conductive lines may be spaced apart from each other in the second direction D2, and may be respectively connected to the bit lines BL. According to one or more embodiments, the lower insulating layer 112 may be interposed between the lower conductive lines, and may extend between the lower conductive lines in the first direction D1.

Semiconductor patterns SP may be respectively disposed on the lower conductive contacts DC. The semiconductor patterns SP may be spaced apart from each other in the first direction D1 and the second direction D2. The semiconductor patterns SP, spaced apart from each other in the first direction D1, among the semiconductor patterns SP may be electrically connected to the corresponding bit line BL through the lower conductive contacts DC spaced apart from each other in the first direction D1. The semiconductor patterns SP, spaced apart from each other in the second direction D2, among the semiconductor patterns SP may be respectively electrically connected to the bit lines BL through the lower conductive contacts DC spaced apart from each other in the second direction D2. Each of the semiconductor patterns SP may be a vertical semiconductor pattern extending long in the third direction D3 vertical to the upper surface 100U of the substrate 100.

The semiconductor patterns SP may include a semiconductor material. For example, the semiconductor patterns SP may include at least one of silicon (e.g., crystalline silicon), germanium (Ge), or silicon-germanium (Si—Ge). According to one or more embodiments, the semiconductor patterns SP may include an oxide semiconductor, such as, but not limited to, at least one of indium gallium zinc oxide (InₓGa_{y}Zn_{z}O), indium gallium silicon oxide (InₓGa_{y}Si_{z}O), indium tin zinc oxide (InₓSn_{y}Zn_{z}O), indium zinc oxide (InₓZn_{y}O), zinc oxide (ZnₓO), zinc tin oxide (ZnₓSn_{y}O), zinc oxynitride (ZnₓO_{y}N), zirconium zinc tin oxide (ZrₓZn_{y}Sn_{z}O), tin oxide (SnₓO), hafnium indium zinc oxide (HfₓIn_{y}Zn_{z}O), gallium zinc tin oxide (GaₓZn_{y}Sn_{z}O), aluminum zinc tin oxide (AlₓZn_{y}Sn_{z}O), ytterbium gallium zinc oxide (YbₓGa_{y}Zn_{z}O), or indium gallium oxide (InₓGa_{y}O). According to one or more embodiments, the semiconductor patterns SP may include a two-dimensional (2D) semiconductor material (e.g., graphene), a three-dimensional (3D) semiconductor material (e.g., carbon nanotube), or a combination thereof.

Gate electrodes GE may be disposed on the bit lines BL and the lower insulating layer 112, and may cross the bit lines BL. The gate electrodes GE may extend in the second direction D2, and may be spaced apart from each other in the first direction D1. The gate electrodes GE may be referred to as word lines. Back-gate electrodes BGE may be disposed on the bit lines BL and the lower insulating layer 112, and may cross the bit lines BL. The back-gate electrodes BGE may extend in the second direction D2, and may be spaced apart from each other in the first direction D1. The gate electrodes GE and the back-gate electrodes BGE may be spaced apart from each other in the first direction D1.

The semiconductor patterns SP, spaced apart from each other in the second direction D2, among the semiconductor patterns SP may be disposed between a corresponding gate electrode GE among the gate electrodes GE and a corresponding back-gate electrode BGE among the back-gate electrodes BGE.

A gate insulating pattern GI may be interposed between the corresponding gate electrode GE and the semiconductor patterns SP spaced apart from each other in the second direction D2, and may extend in the second direction D2. A back-gate insulating pattern BGI may be interposed between the corresponding back-gate electrodes BGE and the semiconductor pattern SP spaced apart from each other in the second direction D2, and may extend in the second direction D2.

A pair of gate electrodes GE, adjacent to each other in the first direction D1, among the gate electrodes GE may be disposed between a pair of semiconductor patterns SP, adjacent to each other in the first direction D1, among the semiconductor patterns SP. The pair of gate electrodes GE and the pair of semiconductor patterns SP may be disposed between a pair of back-gate electrodes BGE, adjacent to each other in the first direction D1, among the back-gate electrodes BGE. The gate insulating pattern GI may be interposed between each of the pair of gate electrodes GE and each of the pair of semiconductor patterns SP. The back-gate insulating pattern BGI may be interposed between each of the pair of back-gate electrodes BGE and each of the pair of semiconductor patterns SP.

The gate electrodes GE and the back-gate electrodes BGE may include a conductive material, and may include, but not be limited to, at least one of a metal (e.g., titanium (Ti), molybdenum (Mo), tungsten (W), copper (Cu), aluminum (Al), tantalum (Ta), ruthenium (Ru), iridium (Ir), cobalt (Co), or the like), a metal silicide (e.g., silicide of titanium (Ti), molybdenum (Mo), tungsten (W), copper (Cu), aluminum (Al), tantalum (Ta), ruthenium (Ru), iridium (Ir), cobalt (Co), or the like), or a conductive metal nitride (e.g., nitride of titanium (Ti), molybdenum (Mo), tungsten (W), copper (Cu), aluminum (Al), tantalum (Ta), ruthenium (Ru), iridium (Ir), cobalt (Co), or the like). According to one or more embodiments, the gate electrodes GE may include molybdenum (Mo). For example, the gate insulating pattern GI and the back-gate insulating pattern BGI may include at least one of silicon oxide (SiO₂) or a high-dielectric material.

A separation insulating pattern 120 may be interposed between the pair of gate electrodes GE, and may extend in the second direction D2. The pair of gate electrodes GE may be electrically separated by the separation insulating pattern 120. The separation insulating pattern 120 may include an insulating material, and may include at least one of an oxide, a nitride, or an oxynitride (e.g., silicon oxide (SiO₂), silicon nitride (Si₃N₄), and/or silicon oxynitride (SiOₓN_{y})). According to one or more embodiments, the separation insulating pattern 120 may include an oxide (e.g., silicon oxide (SiO₂)).

A lower gate capping pattern GCP1 may be disposed between each of the gate electrodes GE and the lower insulating layer 112, and an upper gate capping pattern GCP2 may be disposed on each of the gate electrodes GE. Each of the gate electrodes GE may be interposed between the lower gate capping pattern GCP1 and the upper gate capping pattern GCP2. The lower gate capping pattern GCP1, each of the gate electrodes GE and the upper gate capping pattern GCP2 may be sequentially stacked on one side of each of the semiconductor patterns SP along the third direction D3.

A lower back-gate capping pattern BCP1 may be disposed between each of the back-gate electrodes BGE and the lower insulating layer 112, and an upper back-gate capping pattern BCP2 may be disposed on each of the back-gate electrodes BGE. Each of the back-gate electrodes BGE may be interposed between the lower back-gate capping pattern BCP1 and the upper back-gate capping pattern BCP2. The lower back-gate capping pattern BCP1, each of the back-gate electrodes BGE and the upper back-gate capping pattern BCP2 may be sequentially stacked on the other side of each of the semiconductor patterns SP along the third direction D3.

The lower gate capping pattern GCP1, the upper gate capping pattern GCP2, the lower back-gate capping pattern BCP1 and the upper back-gate capping pattern BCP2 may include an insulating material (e.g., at least one of silicon oxide (SiO₂), silicon nitride (Si₃N₄), silicon oxynitride (SiOₓN_{y}), or the like).

Each of the semiconductor patterns SP may be disposed between a corresponding gate electrode GE among the gate electrodes GE and a corresponding back-gate electrode BGE among the back-gate electrodes BGE. Each of the semiconductor patterns SP may extend between the lower gate capping pattern GCP1 and the lower back-gate capping pattern BCP1, and may be connected to each of the lower conductive contacts DC. Each of the semiconductor patterns SP may extend between the upper gate capping pattern GCP2 and the upper back-gate capping pattern BCP2.

The gate insulating pattern GI may be interposed between each of the semiconductor patterns SP and the corresponding gate electrode GE, and may extend between each of the semiconductor patterns SP and the lower gate capping pattern GCP1, and between each of the semiconductor patterns SP and the upper gate capping pattern GCP2. The back-gate insulating pattern BGI may be interposed between each of the semiconductor patterns SP and the corresponding back-gate electrode BGE, and may extend between each of the semiconductor patterns SP and the lower back-gate capping pattern BCP1, and between each of the semiconductor patterns SP and the upper back-gate capping pattern BCP2. The gate insulating pattern GI and the back-gate insulating pattern BGI may be spaced apart from each other in the first direction D1 with each of the semiconductor patterns SP therebetween. A thickness BGI_T along the first direction D1 of the back-gate insulating pattern BGI may be greater than a thickness GI_T along the first direction D1 of the gate insulating pattern GI.

The separation insulating pattern 120 may be interposed between the pair of gate electrodes GE, and may extend between a pair of lower gate capping patterns GCP1, and between a pair of upper gate capping patterns GCP2.

An anti-oxidation layer 200 may be interposed between each of the pair of gate electrodes GE and the separation insulating pattern 120. The anti-oxidation layer 200 may also be interposed between each of the pair of lower gate capping patterns GCP1 and the separation insulating pattern 120, and between each of the pair of upper gate capping patterns GCP2 and the separation insulating pattern 120.

The anti-oxidation layer 200 may include carbon (C). The anti-oxidation layer 200 may further include a metal. According to one or more embodiments, the anti-oxidation layer 200 may include a metal carbide. The anti-oxidation layer 200 may include the same metal as the gate electrodes GE. For example, the anti-oxidation layer 200 may include molybdenum carbide (MoCₓ). According to one or more embodiments, the anti-oxidation layer 200 may further include an impurity, and the impurity may include at least one of silicon (Si), oxygen (O), or nitrogen (N).

Referring to FIGS. 27 and 28, according to one or more embodiments, the anti-oxidation layer 200 may include a first layer 210 between each of the pair of gate electrodes GE and the separation insulating pattern 120, and a second layer 220 between the first layer 210 and the separation insulating pattern 120. The first layer 210 and the second layer 220 may be interposed between each of the pair of lower gate capping patterns GCP1 and the separation insulating pattern 120, and between each of the pair of upper gate capping patterns GCP2 and the separation insulating pattern 120. The first layer 210 may include a metal and/or carbon (C). For example, the first layer 210 may include a metal carbide. The first layer 210 may include the same metal as the gate electrodes GE. For example, the first layer 210 may include molybdenum carbide (MoCₓ). The second layer 220 may include carbon (C). The second layer 220 may have a smaller metal content than the first layer 210.

Referring back to FIGS. 26 and 27, an upper insulating layer 130 may be disposed on uppermost surfaces of the upper gate capping pattern GCP2, the gate insulating pattern GI, the upper back-gate capping pattern BCP2, the back-gate insulating pattern BGI, the separation insulating pattern 120 and the anti-oxidation layer 200, and may cover the uppermost surfaces of the upper gate capping pattern GCP2, the gate insulating pattern GI, the upper back-gate capping pattern BCP2, the back-gate insulating pattern BGI, the separation insulating pattern 120 and the anti-oxidation layer 200. The upper insulating layer 130 may include an insulating material (e.g., at least one of silicon oxide (SiO₂), silicon nitride (Si₃N₄), silicon oxynitride (SiOₓN_{y}), or the like).

Upper conductive contacts BC may be disposed in the upper insulating layer 130. The upper conductive contacts BC may be respectively disposed on the semiconductor patterns SP, and may be spaced apart from each other in the first direction D1 and the second direction D2. The upper conductive contacts BC may be respectively connected to the semiconductor patterns SP. Each of the upper conductive contacts BC may penetrate the upper insulating layer 130 to be connected to each of the semiconductor patterns SP. The upper conductive contacts BC may include a conductive material such as, but not limited to, at least one of a doped semiconductor material (e.g., doped silicon, doped germanium, or the like), a metal (e.g., titanium (Ti), molybdenum (Mo), tungsten (W), copper (Cu), aluminum (Al), tantalum (Ta), ruthenium (Ru), iridium (Ir), cobalt (Co), or the like), a metal silicide (e.g., silicide of titanium (Ti), molybdenum (Mo), tungsten (W), copper (Cu), aluminum (Al), tantalum (Ta), ruthenium (Ru), iridium (Ir), cobalt (Co), or the like), or a conductive metal nitride (e.g., nitride of titanium (Ti), molybdenum (Mo), tungsten (W), copper (Cu), aluminum (Al), tantalum (Ta), ruthenium (Ru), iridium (Ir), cobalt (Co), or the like).

Data storage patterns DS may be respectively disposed on the upper conductive contacts BC, and may be spaced apart from each other in the first direction D1 and the second direction D2. Each of the data storage patterns DS may be electrically connected to each of the semiconductor patterns SP through each of the upper conductive contacts BC. Each of the semiconductor patterns SP may be electrically connected to a corresponding bit line BL among the bit lines BL through each of the lower conductive contacts DC.

For example, each of the data storage patterns DS may be a capacitor including a lower electrode, an upper electrode and a dielectric layer therebetween. In such a case, the semiconductor device, according to the present disclosure, may be and/or may include a dynamic random access memory (DRAM) device. As another example, each of the data storage patterns DS may be and/or may include a magnetic tunnel junction (MTJ), and in such a case, the semiconductor device, according to the present disclosure, may be and/or may include a magnetic random access memory (MRAM) device. As another example, each of the data storage patterns DS may include a phase-change material and/or a variable resistance material, and in such a case, the semiconductor device, according to the present disclosure, may be and/or may include a phase-change random access memory (PRAM) device, and/or a resistive random access memory (ReRAM) device. However, the present disclosure is not limited thereto, and the data storage pattern DS may include various structures and/or materials capable of storing data.

According to embodiments of the present disclosure, since the anti-oxidation layer 200 is interposed between each of the gate electrodes GE and the separation insulating pattern 120, the gate electrodes GE may be prevented and/or suppressed from being oxidized during formation of the separation insulating pattern 120. Accordingly, resistance of the gate electrodes GE may be prevented and/or suppressed from increasing, when compared to a related semiconductor device. According to one or more embodiments, the gate electrodes GE may include a metal (e.g., molybdenum (Mo)). In such a case, the gate electrodes GE may have a great conductivity at a relatively smaller thickness, and thus the gate electrodes GE may be relatively highly integrated. Accordingly, electrical characteristics of vertical channel transistors including the gate electrodes GE may be improved, when compared to a related semiconductor device, and thus, the semiconductor device including the vertical channel transistors may be relatively highly integrated.

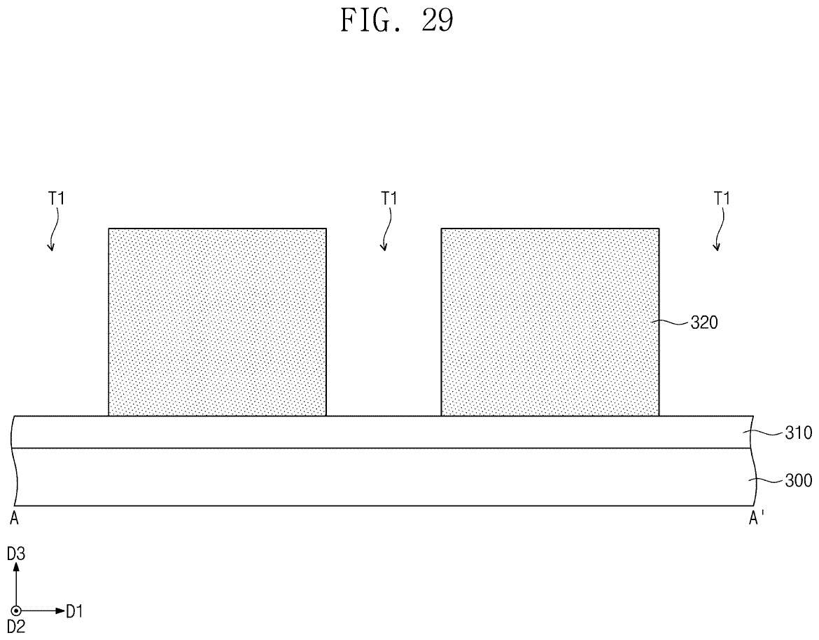

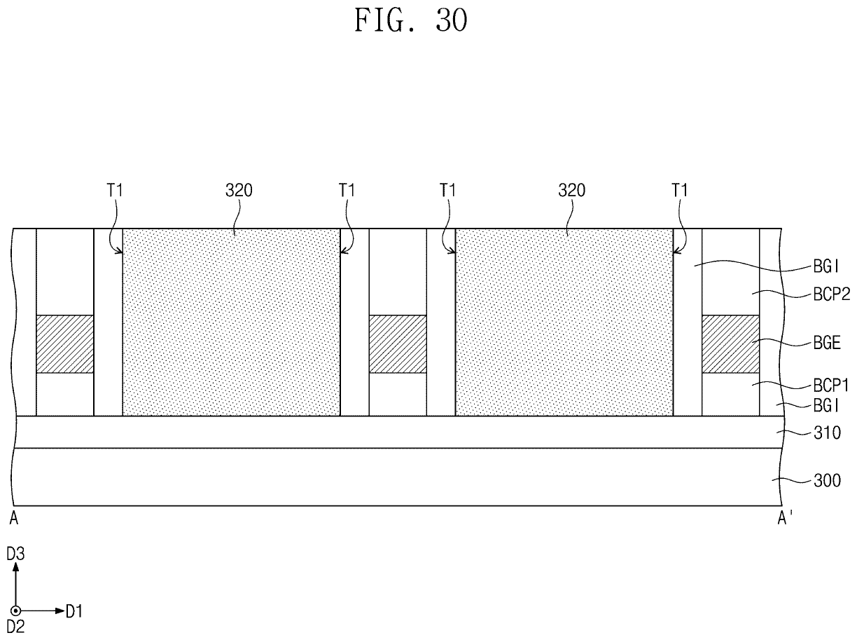

FIGS. 29 to 34 are diagrams illustrating the method for manufacturing the semiconductor device, according to one or more the present disclosure, and are cross-sectional views corresponding to A-A′ of FIG. 26. The method for manufacturing the semiconductor device described with reference to FIGS. 29 to 34 may include and/or may be similar in many respects to the semiconductor described above with reference to FIGS. 26 to 28, and may include additional features not mentioned above. Consequently, repeated descriptions of the method for manufacturing the semiconductor device of FIGS. 29 to 34 described above with reference to FIGS. 26 to 28 may be omitted for the sake of brevity.

Referring to FIGS. 26 and 29, a sacrificial insulating layer 310 may be formed on a sacrificial substrate 300. The sacrificial substrate 300 may include a semiconductor material, and the sacrificial insulating layer 310 may include an insulating material. A semiconductor layer 320 may be formed on the sacrificial insulating layer 310. The semiconductor layer 320 may include a semiconductor material such as, but not limited to, at least one of silicon (e.g., crystalline silicon), germanium (Ge), or silicon-germanium (Si—Ge). According to one or more embodiments, the semiconductor layer 320 may include an oxide semiconductor such as, but not limited to, at least one of indium gallium zinc oxide (InₓGa_{y}Zn_{z}O), indium gallium silicon oxide (InₓGa_{y}Si_{z}O), indium tin zinc oxide (InₓSn_{y}Zn_{z}O), indium zinc oxide (InₓZn_{y}O), zinc oxide (ZnₓO), zinc tin oxide (ZnₓSn_{y}O), zinc oxynitride (ZnₓOy_{N}), zirconium zinc tin oxide (ZrₓZn_{y}Sn_{z}O), tin oxide (SnₓO), hafnium indium zinc oxide (HfₓIn_{y}Zn_{z}O), gallium zinc tin oxide (GaₓZn_{y}Sn_{z}O), aluminum zinc tin oxide (AlₓZn_{y}Sn_{z}O), ytterbium gallium zinc oxide (YbₓGa_{y}Zn_{z}O), or indium gallium oxide (InₓGa_{y}O). According to one or more embodiments, the semiconductor layer 320 may include a two-dimensional (2D) semiconductor material (e.g., graphene), a three-dimensional (3D) semiconductor material (e.g., carbon nanotube), or a combination thereof.

First trenches T1 may be formed in the semiconductor layer 320. Each of the first trenches T1 may extend in the third direction D3 to penetrate the semiconductor layer 320. The first trenches T1 may be spaced apart from each other in the first direction D1, and may extend in the second direction D2. The first trenches T1 may be formed by patterning the semiconductor layer 320.

Referring to FIGS. 26 and 30, the back-gate insulating pattern BGI may be formed so as to partially fill each of the first trenches T1. The back-gate insulating pattern BGI may be formed on an inner side surface of each of the first trenches T1, and a pair of back-gate insulating patterns BGI adjacent to each other may be spaced apart from each other in each of the first trenches T1 in the first direction D1. For example, forming the back-gate insulating pattern BGI may include forming a back-gate insulating layer conformally covering an inner surface of each of the first trenches T1, and partially removing the back-gate insulating layer on a bottom surface of each of the first trenches T1. As another example, partially removing the back-gate insulating layer may be performed in an anisotropic etching process.

The lower back-gate capping pattern BCP1 may be formed so as to fill a lower portion of each of the first trenches T1. For example, forming the lower back-gate capping pattern BCP1 may include forming a lower back-gate capping layer that fills the lower portion of each of the first trenches T1, and recessing the lower back-gate capping layer until the lower back-gate capping layer is left at a desired thickness in each of the first trenches T1.

The back-gate electrode BGE may be formed so as to partially fill each of the first trenches T1. For example, forming the back-gate electrode BGE may include forming a back-gate electrode layer that partially fills each of the first trenches T1, and recessing the back-gate electrode layer until the gate electrode layer is left at a desired thickness in each of the first trenches T1.

The upper back-gate capping pattern BCP2 may be formed so as to fill a remaining portion of each of the first trenches T1. For example, forming the upper back-gate capping pattern BCP2 may include forming, on the semiconductor layer 320, an upper back-gate capping layer that fills the remaining portion of each of the first trenches T1, and planarizing the upper back-gate capping layer until an upper surface of the semiconductor layer 320 is exposed.

The lower back-gate capping pattern BCP1, the back-gate electrode BGE, and the upper back-gate capping pattern BCP2 may be interposed between the pair of back-gate insulating patterns BGI.

Separation trenches may be formed in the semiconductor layer 320. The separation trenches may be formed between the first trenches T1. Between a pair of first trenches T1, adjacent to each other in the first direction D1, among the first trenches T1, the separation trenches may extend in the first direction D1, and may be spaced apart from each other in the second direction D2. Each of the separation trenches may extend in the third direction D3 to penetrate the semiconductor layer 320. Separation patterns may be formed so as to fill the separation trenches. The separation patterns may include an insulating material such as, but not limited to, silicon oxide (SiO₂), silicon nitride (Si₃N₄), silicon oxynitride (SiOₓN_{y}), or the like.

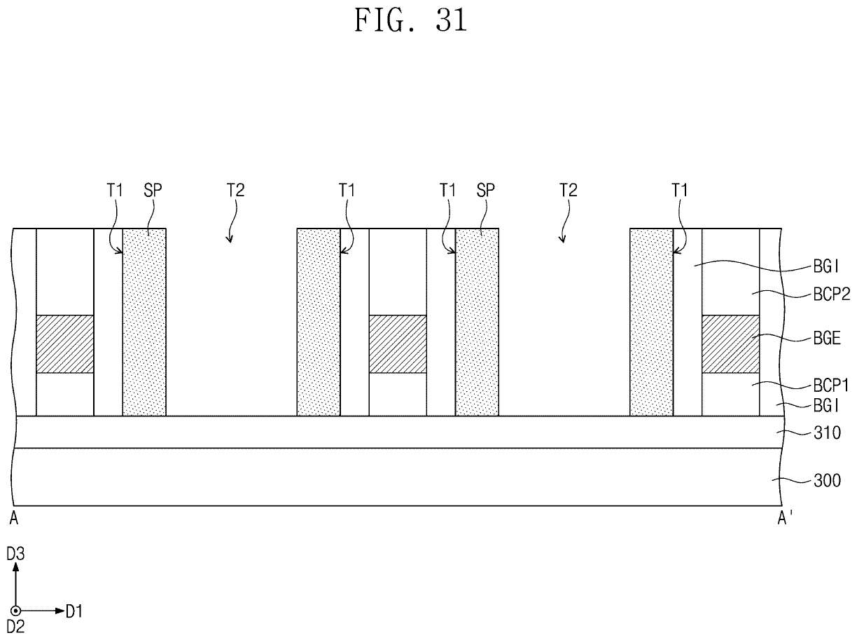

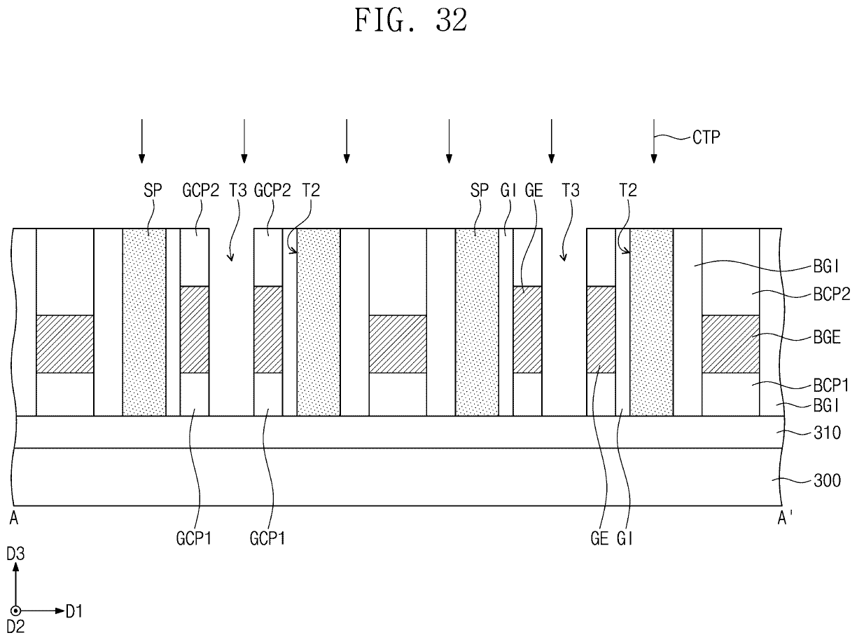

Referring to FIGS. 26 and 31, second trenches T2 may be formed in the semiconductor layer 320. Each of the second trenches T2 may be formed between a pair of first trenches T1, adjacent to each other in the first direction D1, among the first trenches T1, and may extend in the third direction D3 to penetrate the semiconductor layer 320 and the separation patterns. The second trenches T2 may be spaced apart from in the first direction D1, and may extend in the second direction D2. The first trenches T1 and the second trenches T2 may be alternately arranged along the first direction D1. The second trenches T2 may be formed by patterning the semiconductor layer 320 and the separation patterns. A plurality of semiconductor patterns SP may be formed by patterning the semiconductor layer 320 by the second trenches T2. The semiconductor patterns SP may be spaced apart from each other in the first direction D1 and the second direction D2. Each of the semiconductor patterns SP may be a vertical semiconductor pattern extending long in the third direction D3.

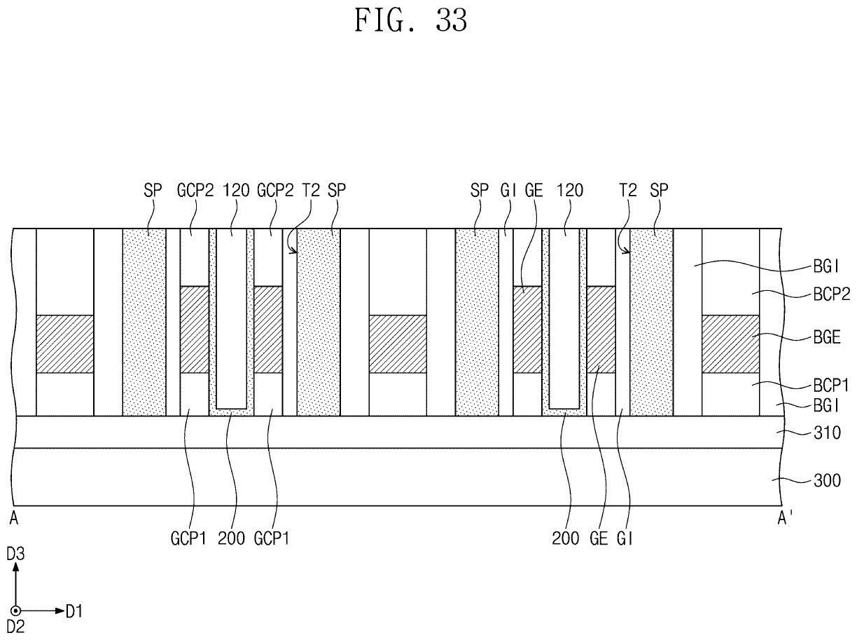

Referring to FIGS. 26 and 32, the gate insulating pattern GI may be formed so as to partially fill each of the second trenches T2. The gate insulating pattern GI may be formed on an inner side surface of each of the second trenches T2, and a pair of gate insulating patterns GI adjacent to each other may be spaced apart from each other in each of the second trenches T2 in the first direction D1. For example, forming the gate insulating pattern GI may include forming a gate insulating layer conformally covering an inner surface of each of the second trenches T2, and partially removing the gate insulating layer on a bottom surface of each of the second trenches T2. For example, partially removing the gate insulating layer may be performed in an anisotropic etching process.

The lower gate capping pattern GCP1 may be formed so as to fill a lower portion of each of the second trenches T2. For example, forming the lower gate capping pattern GCP1 may include forming a lower gate capping layer that fills a lower portion of each of the second trenches T2, and recessing the lower gate capping layer until the lower gate capping layer is left at a desired thickness in each of the second trenches T2.

The gate electrode GE may be formed so as to partially fill each of the second trenches T2. For example, forming the gate electrode GE may include forming a gate electrode layer that partially fills each of the second trenches T2, and recessing the gate electrode layer until the gate electrode layer is left at a desired thickness in each of the second trenches T2.

The upper gate capping pattern GCP2 may be formed so as to fill a remaining portion of each of the second trenches T2. For example, forming the upper gate capping pattern GCP2 may include forming an upper gate capping layer that fills a remaining portion of each of the second trenches T2 on the semiconductor patterns SP, and planarizing the upper gate capping layer until upper surfaces of the semiconductor patterns SP are exposed.

The lower gate capping pattern GCP1, the gate electrode GE, and the upper gate capping pattern GCP2 may be interposed between the pair of gate insulating patterns GI.

A third trench T3 may be formed so as to penetrate the lower gate capping pattern GCP1, the gate electrode GE and the upper gate capping pattern GCP2. The third trench T3 may be formed inside each of the second trenches T2, and may extend in the second direction D2. The lower gate capping pattern GCP1 may be separated into a pair of lower gate capping patterns GCP1 by the third trench T3. The gate electrode GE may be separated into a pair of gate electrodes GE spaced apart from each other in the first direction D1 by the third trench T3. The upper gate capping pattern GCP2 may be separated into a pair of upper gate capping patterns GCP2 spaced apart from each other in the first direction D1 by the third trench T3. The third trench T3 may expose side surfaces of the pair of lower gate capping patterns GCP1, the pair of gate electrodes GE, and the pair of upper gate capping patterns GCP2.

A carbon treatment process (CTP) may be performed on the exposed side surfaces of the pair of lower gate capping patterns GCP1, the pair of gate electrodes GE and the pair of upper gate capping patterns GCP2. The carbon treatment process (CTP) may be substantially similar and/or the same as the carbon treatment process (CTP) described with reference to FIGS. 3 and 4.

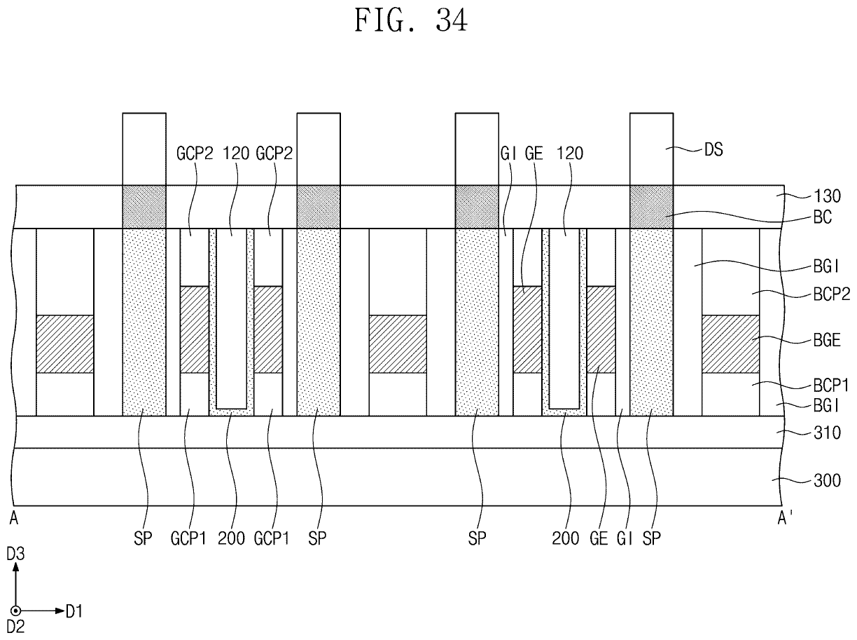

Referring to FIGS. 26 and 33, the anti-oxidation layer 200 may be formed, by the carbon treatment process (CTP), on the exposed side surfaces of the pair of lower gate capping patterns GCP1, the pair of gate electrodes GE and the pair of upper gate capping patterns GCP2. The anti-oxidation layer 200 may also be formed on an upper surface of the sacrificial insulating layer 310 between the pair of lower gate capping patterns GCP1. The anti-oxidation layer 200 may be formed in a substantially similar and/or the same method as the anti-oxidation layer 200 described with reference to FIGS. 3 and 4.

The separation insulating pattern 120 may be formed in the third trench T3. For example, forming the separation insulating pattern 120 may include forming a separation insulating layer that covers uppermost surfaces of the upper gate capping pattern GCP2, the gate insulating pattern GI, the upper back-gate capping pattern BCP2, the back-gate insulating pattern BGI and the semiconductor patterns SP, and that fills the third trench T3, and planarizing the separation insulating layer until the uppermost surfaces of the upper gate capping pattern GCP2, the gate insulating pattern GI, the upper back-gate capping pattern BCP2, the back-gate insulating pattern BGI and the semiconductor patterns SP are exposed.

According to the present disclosure, the anti-oxidation layer 200 may prevent and/or suppress surfaces of the gate electrodes GE from being oxidized during formation of the separation insulating pattern 120, and thus, resistance of the gate electrodes GE may be prevented and/or suppressed from increasing, when compared to a related semiconductor device.

Referring to FIGS. 26 and 34, the upper insulating layer 130 may be formed so as to cover the uppermost surfaces of the upper gate capping pattern GCP2, the gate insulating pattern GI, the separation insulating pattern 120, the anti-oxidation layer 200, the upper back-gate capping pattern BCP2, the back-gate insulating pattern BGI and the semiconductor patterns SP.

The upper conductive contacts BC may be formed in the upper insulating layer 130. The upper conductive contacts BC may be spaced apart from each other in the first direction D1 and the second direction D2. Each of the upper conductive contacts BC may penetrate the upper insulating layer 130 to be connected to each of the semiconductor patterns SP. For example, forming the upper conductive contacts BC may include forming upper contact holes penetrating the upper insulating layer 130 and exposing the semiconductor patterns SP, forming, on the upper insulating layer 130, an upper contact layer that fills the upper contact holes, and planarizing the upper contact layer until the upper contact layer is exposed to an upper surface of the upper insulating layer 130. The upper conductive contacts BC may be respectively locally formed in the upper contact holes in the planarization process.

The data storage patterns DS may be respectively formed on the upper conductive contacts BC. For example, forming the data storage patterns DS may include forming a data storage layer on the upper insulating layer 130 and patterning the data storage layer.

Referring back to FIGS. 26 and 27, a structure illustrated in FIG. 34 may be turned over upside down, and the sacrificial substrate 300 and the sacrificial insulating layer 310 may be removed. Accordingly, lowermost surfaces of the lower gate capping pattern GCP1, the gate insulating pattern GI, the separation insulating pattern 120, the anti-oxidation layer 200, the lower back-gate capping pattern BCP1, the back-gate insulating pattern BGI and the semiconductor patterns SP may be exposed.

The lower insulating layer 112 may be formed so as to cover the lowermost surfaces of the lower gate capping pattern GCP1, the gate insulating pattern GI, the separation insulating pattern 120, the anti-oxidation layer 200, the lower back-gate capping pattern BCP1, the back-gate insulating pattern BGI and the semiconductor patterns SP.

The lower conductive contacts DC may be formed in the lower insulating layer 112. The lower conductive contacts DC may be spaced apart from each other in the first direction D1 and the second direction D2. Each of the lower conductive contacts DC may penetrate the lower insulating layer 112 to be connected to each of the semiconductor patterns SP. For example, forming the lower conductive contacts DC may include forming lower contact holes penetrating the lower insulating layer 112 and exposing the semiconductor patterns SP, forming a lower contact layer that fills the lower contact holes on the lower insulating layer 112, and planarizing the lower contact lower until the lower contact layer is exposed to an upper surface of the lower insulating layer 112. The lower conductive contacts DC may be respectively locally formed in the lower contact holes in the planarization process.

The bit lines BL may be formed on the lower insulating layer 112. The bit lines BL may extend in the first direction D1, and may be spaced apart from each other in the second direction D2. Insulating patterns may be interposed between the bit lines BL, and may extend between the bit lines BL in the first direction D1. Each of the bit lines BL may be connected to the lower conductive contacts DC, spaced apart from in the first direction D1, among the lower conductive contacts DC in common. The lower conductive contacts DC, spaced apart from each other in the second direction D2, among the lower conductive contacts DC may be respectively connected to the bit lines BL.

The substrate 100 may be formed on the bit lines BL. According to one or more embodiments, the substrate 100 may include the first substrate SUB1 and the peripheral circuit structure PS of FIG. 10, and may further include an insulating layer covering the peripheral circuit structure PS. According to other embodiments, the substrate 100 may include the second substrate SUB2 of FIG. 11, and may further include an insulating layer on the second substrate SUB2.

According to the present disclosure, an anti-oxidation layer including carbon (C) may be interposed between a gate electrode and an insulating layer. Accordingly, the gate electrode may be prevented and/or suppressed from being oxidized during formation of the insulating layer, Thereby, resistance of the gate electrode may be prevented and/or suppressed from increasing, when compared to a related semiconductor device. In addition, the gate electrode may include molybdenum (Mo), and in this case, the gate electrode may have a great conductivity at a relatively small thickness. Accordingly, the gate electrode may be relatively highly integrated. Accordingly, electrical characteristics of a transistor including the gate electrode may be improved, when compared to a related semiconductor device, and a semiconductor device including the transistor may be relatively highly integrated.

The above description of embodiments of the present disclosure provides an example for description of the present disclosure. Therefore, the present disclosure is not limited to the above embodiments, and it is to be understood that various modifications and changes such as combining the above embodiments may be made by those skilled in the art within the technical spirit of the present disclosure.

What is claimed is:

1. A semiconductor device comprising:
gate electrodes spaced apart from each other on a lower structure in a horizontal direction that is parallel to an upper surface of the lower structure;
an insulating layer between the gate electrodes; and
an anti-oxidation layer between each of the gate electrodes and the insulating layer,
wherein the anti-oxidation layer comprises a metal carbide.

2. The semiconductor device of claim 1, wherein the gate electrodes comprise a metal.

3. The semiconductor device of claim 2, wherein the gate electrodes and the anti-oxidation layer comprise a same metal.

4. The semiconductor device of claim 1, wherein the insulating layer comprises an oxide.

5. The semiconductor device of claim 1, wherein the gate electrodes comprise molybdenum (Mo), and
wherein the anti-oxidation layer comprises molybdenum carbide (MoCₓ).

6. The semiconductor device of claim 1, wherein the anti-oxidation layer extends between the lower structure and the insulating layer.

7. The semiconductor device of claim 1, wherein the anti-oxidation layer comprises:
a first layer between each of the gate electrodes and the insulating layer; and
a second layer between the first layer and the insulating layer,
wherein the first layer comprises the metal carbide, and
wherein the second layer comprises carbon.

8. The semiconductor device of claim 1, further comprising:
semiconductor patterns spaced apart from each other on the lower structure in the horizontal direction,
wherein the gate electrodes are between the semiconductor patterns, and
wherein the semiconductor patterns and the gate electrodes extend in a vertical direction vertical to the upper surface of the lower structure.

9. The semiconductor device of claim 8, further comprising:
a gate insulating pattern interposed between each of the semiconductor patterns and each of the gate electrodes, and extending in the vertical direction.

10. A semiconductor device comprising:
a bit line extending on a substrate in a first direction that is parallel to an upper surface of the substrate;
vertical semiconductor patterns spaced apart from each other on the bit line in the first direction, and extending in a vertical direction vertical to the upper surface of the substrate;
gate electrodes spaced apart from each other between the vertical semiconductor patterns in the first direction, and extending in a second direction parallel to the upper surface of the substrate and crossing the first direction;
an insulating layer between the gate electrodes; and
an anti-oxidation layer between each of the gate electrodes and the insulating layer,
wherein the anti-oxidation layer comprises carbon.

11. The semiconductor device of claim 10, wherein the gate electrodes comprise a metal.

12. The semiconductor device of claim 10, wherein the anti-oxidation layer comprises metal carbide.

13. The semiconductor device of claim 10, wherein the gate electrodes and the anti-oxidation layer comprise a same metal.

14. The semiconductor device of claim 10, further comprising a gate insulating pattern interposed between each of the vertical semiconductor patterns and each of the gate electrodes.

15. The semiconductor device of claim 14, further comprising a horizontal semiconductor pattern disposed on the bit line between the vertical semiconductor patterns,
wherein the horizontal semiconductor pattern extends in the first direction and is coupled with lower portions of the vertical semiconductor patterns,
wherein the gate electrodes are on the horizontal semiconductor pattern, and
wherein the gate insulating pattern extends between each of the gate electrodes and the horizontal semiconductor pattern.

16. The semiconductor device of claim 15, wherein the gate insulating pattern extends between the insulating layer and the horizontal semiconductor pattern.

17. The semiconductor device of claim 16, wherein the anti-oxidation layer is interposed between the insulating layer and the gate insulating pattern.

18. The semiconductor device of claim 14, further comprising:
lower conductive contacts respectively interposed between the vertical semiconductor patterns and the bit line; and
a lower insulating layer between the lower conductive contacts,
wherein the gate electrodes and the insulating layer are on the lower insulating layer, and
wherein the anti-oxidation layer is interposed between the lower insulating layer and the insulating layer.

19. The semiconductor device of claim 10, wherein the anti-oxidation layer comprises:
a first layer between each of the gate electrodes and the insulating layer; and
a second layer between the first layer and the insulating layer, and
wherein the first layer comprises metal carbide, and
wherein the second layer comprises carbon.

20. The semiconductor device of claim 10, wherein the gate electrodes comprise molybdenum (Mo).
